(19) United States
(12) Patent Application Publication
(10) Pub. No.: US 2026/0040765 A1
(43) Pub. Date: Feb. 5, 2026

(54) DISPLAY PANEL, PREPARATION METHOD THEREOF, AND DISPLAY DEVICE

(71) Applicant: Hefei Visionox Technology Co., Ltd., Hefei (CN)

(72) Inventors: Zhiwei ZHOU, Hefei (CN); Jinfang ZHANG, Hefei (CN); Yulong MA, Hefei (CN); Chuanru DAI, Hefei (CN); Jingxi HAN, Hefei (CN)

(73) Assignee: Hefei Visionox Technology Co., Ltd., Hefei (CN)

(21) Appl. No.: 19/185,478

(22) Filed: Apr. 22, 2025

(30) Foreign Application Priority Data
Jul. 31, 2024 (CN) 202411051265.4

(51) Int. Cl. H10K 59/122; H10K 59/12; H10K 59/80

(52) U.S. Cl. CPC H10K 59/122; H10K 59/1201; H10K 59/873

(57) ABSTRACT

A display panel, a preparation method thereof and a display device. The display panel includes a substrate, an isolation structure, multiple light-emitting elements and a protective layer. The isolation structure is disposed on one side of the substrate and includes a first isolation structure located in a first region and a second isolation structure located at a junction between the first region and a second region. The first isolation structure is provided with multiple first isolation openings. The multiple light-emitting elements are disposed on the side of the substrate and correspond to the multiple first isolation openings respectively, and at least part of a light-emitting element is disposed within a corresponding first isolation opening. The protective layer covers at least part of the sidewall of the second isolation structure facing the second region.

### CROSS-REFERENCE TO RELATED APPLICATION(S)

This application claims priority to Chinese Patent Application No. 202411051265.4 filed Jul. 31, 2024, the disclosure of which is incorporated herein by reference in its entirety.

### TECHNICAL FIELD

The present application relates to the field of display technology and, in particular, to a display panel, a preparation method thereof, and a display device.

### BACKGROUND

Organic light-emitting diode (OLED) display technology is regarded as the most promising new flat-panel display technology for the next generation. Compared with liquid crystal display technology, the OLED display technology has the advantages of low consumption, low cost, self-luminescence, a wide viewing angle, and a fast response speed. However, current OLED display panels have issues with poor display performance.

### SUMMARY

Embodiments of the present application provide a display panel, a preparation method thereof, and a display device.

In a first aspect, embodiments of the present application provide a display panel. The display panel includes a first region and a second region adjacent to the first region and includes a substrate, an isolation structure, a plurality of light-emitting elements, and a protective layer.

The isolation structure is disposed on one side of the substrate and includes a first isolation structure located in the first region and a second isolation structure located at a junction between the first region and the second region, where the first isolation structure is provided with a plurality of first isolation openings.

The plurality of light-emitting elements are disposed on the side of the substrate and correspond to the plurality of first isolation openings, where at least part of a light-emitting element of the plurality of light-emitting elements is disposed within a corresponding first isolation opening of the plurality of first isolation openings.

The protective layer covers at least part of a sidewall of the second isolation structure facing the second region.

Embodiments of the present application provide another display panel. The display panel includes a display region and a bezel region that are adjacent to each other, and includes an array substrate, a plurality of light-emitting elements, a metal structure, and a protective layer.

The plurality of light-emitting elements are spaced apart on one side of the array substrate.

The metal structure is disposed on the side of the array substrate and includes a first portion and a second portion that are electrically connected, where the first portion is located in the display region and configured to space apart adjacent ones of the plurality of light-emitting elements, and the second portion is located in the bezel region and electrically connected to wires in the array substrate.

The protective layer at least covers at least part of a sidewall of the second portion.

In the display panel provided in the embodiments of the present application, the protective layer is disposed so that the protective layer can cover the at least part of the sidewall of the second portion of the metal structure, thereby protecting the sidewall of the second portion. In this manner, in the process of manufacturing the display panel, the erosion of the sidewall of the second portion by a process solution is weakened so that the light-emitting performance of the plurality of light-emitting elements can be prevented from being affected due to the impact on the plurality of light-emitting elements caused by ion precipitation in the second portion.

Embodiments of the present application provide a preparation method for a display panel. The display panel includes a first region and a second region adjacent to the first region.

The preparation method includes the steps below.

A substrate is provided.

An isolation structure, a plurality of light-emitting elements and a protective layer are formed on one side of the substrate, where the isolation structure includes a first isolation structure located in the first region and a second isolation structure located at a junction between the first region and the second region, where the first isolation structure is provided with a plurality of first isolation openings; the plurality of light-emitting elements correspond to the plurality of first isolation openings respectively, and at least part of a light-emitting element of the plurality of light-emitting elements is disposed within a corresponding first isolation opening of the plurality of first isolation openings; at least part of a sidewall of the second isolation structure facing the second region is covered with the protective layer.

### BRIEF DESCRIPTION OF DRAWINGS

FIG. 1 is a partial cross-section view of a display panel according to some embodiments of the present application.

FIG. 2 is a plane diagram of a display panel shown in FIG. 1.

FIG. 3 is another plane diagram of a display panel shown in FIG. 1.

FIG. 4 is a partial plane diagram of a display panel shown in FIG. 3.

FIG. 5 is yet another plane diagram of a display panel shown in FIG. 1.

FIG. 6 is a partial plane diagram of a display panel shown in FIG. 5.

FIG. 7 is a partial cross-section view of a display panel shown in FIG. 5.

FIG. 8 is a partial cross-section view of a display panel shown in FIG. 1.

FIG. 9 is another partial cross-section view of a display panel according to some embodiments of the present application.

FIG. 10 is yet another partial cross-section view of a display panel according to some embodiments of the present application.

FIG. 11 is still yet another partial cross-section view of a display panel according to some embodiments of the present application.

FIG. 12 is a partial cross-section view of a display panel shown in FIG. 11.

FIGS. 13 and 14 are cross-section views of a display panel shown in FIG. 1 in a preparation process.

FIG. 15 is still yet another partial cross-section view of a display panel according to some embodiments of the present application.

FIG. 16 is still yet another partial cross-section view of a display panel according to some embodiments of the present application.

FIG. 17 is still yet another plane diagram of some structures of a display panel according to some embodiments of the present application.

FIG. 18 is a cross-section view of a second portion and a protective layer of an insolation structure in a display panel shown in FIG. 17.

FIG. 19 is another cross-section view of a second portion and a protective layer of an insolation structure in a display panel shown in FIG. 17.

FIG. 20 is yet another cross-section view of a second portion and a protective layer of an insolation structure in a display panel shown in FIG. 17.

FIG. 21 is a flowchart of a preparation method for a display panel according to some embodiments of the present application.

### DETAILED DESCRIPTION

To facilitate the understanding of the present application, the present application is described more comprehensively below with reference to the relevant drawings. Preferred embodiments of the present application are shown in the drawings. However, the present application may be implemented in many different forms and is not limited to the embodiments described herein. On the contrary, these embodiments are provided to make the disclosure of the present application understood more thoroughly and completely.

It is to be understood that while terms such as “first” and “second” may be used herein for describing various elements, these terms are used for distinguishing different components instead of representing any order, quantity, or significance. These terms are only used for distinguishing one element from another. For example, without departing from the scope of the present application, a first element may be referred to as a second element, and similarly, the second element may be referred to as the first element. The term such as “including” or “comprising” means that elements or objects in front of the term cover elements or objects and their equivalents listed in the back of the term, but does not exclude other elements or objects.

The organic light-emitting diode (OLED) display technology is regarded as the most promising new flat-panel display technology for the next generation. Compared with the liquid crystal display technology, the OLED display technology has the advantages of low consumption, low cost, self-luminescence, a wide viewing angle, and a fast response speed. In a related OLED display panel, a substrate is provided with an isolation structure which defines a first isolation opening, a second isolation opening, and a third isolation opening. A red sub-pixel, a green sub-pixel, and a blue sub-pixel are disposed within the first isolation opening, the second isolation opening, and the third isolation opening respectively. Cathodes of the red sub-pixel, the green sub-pixel, and the blue sub-pixel are electrically connected to the isolation structure. The red sub-pixel, the green sub-pixel, and the blue sub-pixel are manufactured sequentially using a patterning process and are protected by corresponding encapsulation portions in the patterning process. However, such OLED display panels have poor display.

Through research, the inventors have found that an etching solution is prone to erode the sidewall of an edge region of the isolation structure in the process of patterning the sub-pixels, resulting in ion precipitation in the isolation structure, and the precipitated ions are prone to flow into the isolation openings of the isolation structure in the cleaning process and are doped into light-emitting elements in the subsequent process of manufacturing the light-emitting elements to affect the light-emitting performance and service life of the light-emitting elements, resulting poor display.

To solve the preceding problem, embodiments of the present application provide a display panel, a preparation method thereof, and a display device. The embodiments are illustrated below in conjunction with the drawings.

The composition, preparation and other contents of the isolation structure mentioned below are further described in patents CN118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072 and CN116685174A for reference.

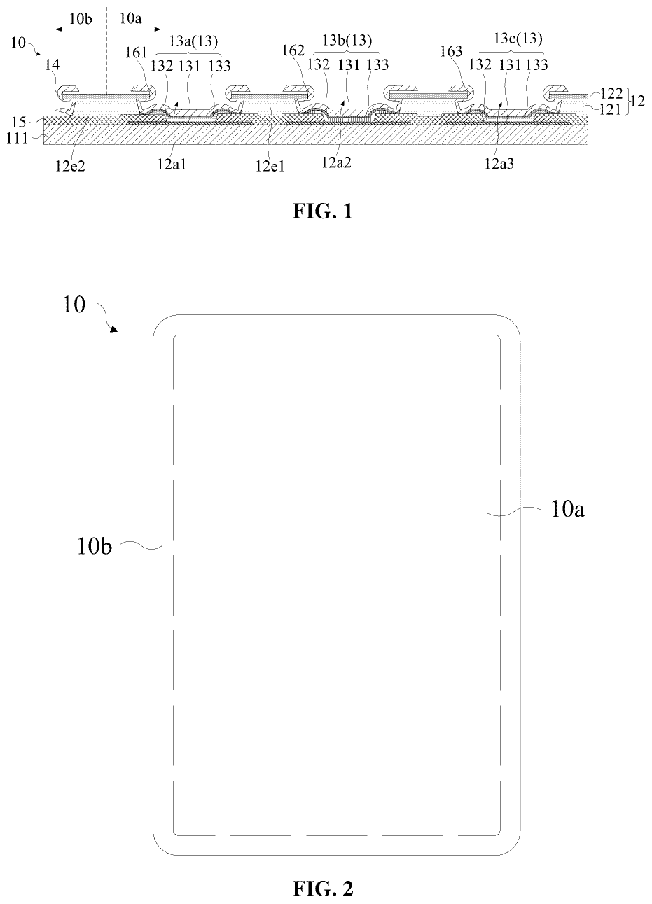

In a first aspect, referring to FIG. 1, embodiments of the present application provide a display panel 10. The display panel 10 may be an organic light-emitting diode (OLED) display panel 10 or a quantum-dot light-emitting diode (QLED) display panel 10.

Specifically, the display panel 10 includes a first region 10a and a second region 10b adjacent to the first region 10a. The display panel 10 includes a substrate 111, an isolation structure 12, multiple light-emitting elements 13, and a protective layer 14. The isolation structure 12 is disposed on one side of the substrate 111 and includes a first isolation structure 12e1 located in the first region 10a and a second isolation structure 12e2 located at a junction between the first region 10a and the second region 10b. The first isolation structure 12e1 is provided with multiple first isolation openings 12a. The multiple light-emitting elements 13 are disposed on the side of the substrate 111 and correspond to the multiple first isolation openings 12a. At least part of a light-emitting element 13 of the multiple light-emitting elements 13 is disposed within a corresponding first isolation opening 12a of the multiple first isolation openings 12a. The protective layer 14 covers at least part of the sidewall of the second isolation structure 12e2 facing the second region 10b.

The isolation structure 12 may be divided into regions herein. Exemplarily, referring to FIG. 1, the isolation structure 12 located on the right side of a dotted line (that is, the first region 10a) is the first isolation structure 12e1, and the isolation structure 12 located on the left side of the dotted line (that is, the second region 10b) is the second isolation structure 12e2.

It is to be understood that the multiple light-emitting elements 13 may correspond to the multiple first isolation openings 12a in a “multiple-to-one” or “one-to-one” relationship. The multiple light-emitting elements 13 in one-to-one correspondence with the multiple first isolation openings 12a is used as an example in the embodiments of the present application for illustration.

In the display panel 10 provided in the embodiments of the present application, the protective layer 14 is disposed so that the protective layer 14 covers the at least part of the sidewall of the second isolation structure 12e2 facing the second region 10b, thereby protecting the second isolation structure 12e2. In this manner, in the process of manufacturing the display panel 10, the erosion of the sidewall of the second isolation structure 12e2 by a process solution (such as the etching solution) is weakened. For one aspect, this helps prevent the light-emitting performance of the multiple light-emitting elements 13 from being affected due to the impact on the multiple light-emitting elements 13 caused by ion precipitation in the second isolation structure 12e2; for another aspect, this helps reduce the risk of capsulation failure caused by the erosion of the second isolation structure 12e2, thereby improving the reliability of the display panel 10.

In some embodiments, referring to FIG. 2, the first region 10a is a display region, and the second region 10b is a bezel region. In this manner, this is equivalent to that the protective layer 14 is disposed on the sidewall of the isolation structure 12 located at the junction between the display region and the bezel region, which helps prevent the light-emitting performance of the multiple light-emitting elements 13 from being affected due to ion precipitation caused by the erosion of the sidewall of the isolation structure 12 located at the junction between the display region and the bezel region by the etching solution.

In some embodiments, the bezel region is around the periphery of the display region.

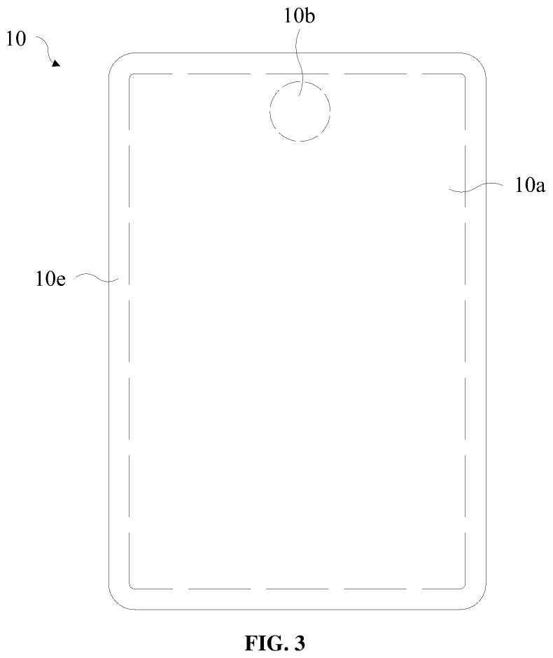

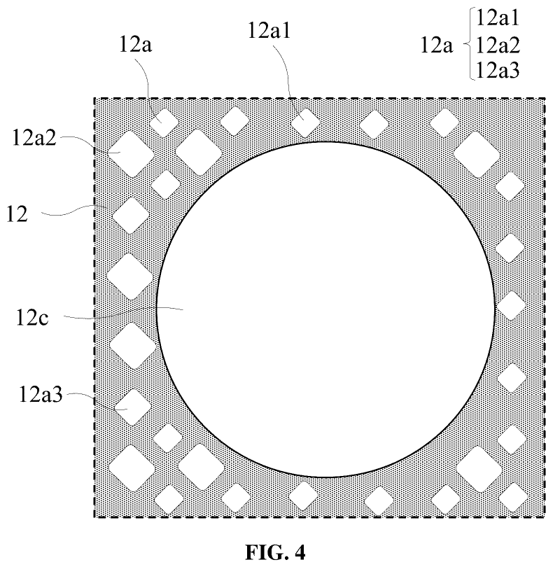

In some embodiments, referring to FIGS. 3 and 4, the first region 10a is the display region, and the second region 10b is a hole-punch region. The transmittance of the hole-punch region is greater than the transmittance of the display region. The isolation structure 12 is provided with a first light-transmissive hole 12c located in the hole-punch region.

In some embodiments, the display region is around the periphery of the hole-punch region.

It is to be understood that the hole-punch region of the display panel 10 may be provided with an under-screen module. The under-screen module may be an under-screen camera module or an under-screen fingerprint module. As shown in FIG. 3, the display panel 10 may further include a bezel region 10e around the periphery of the first region 10a.

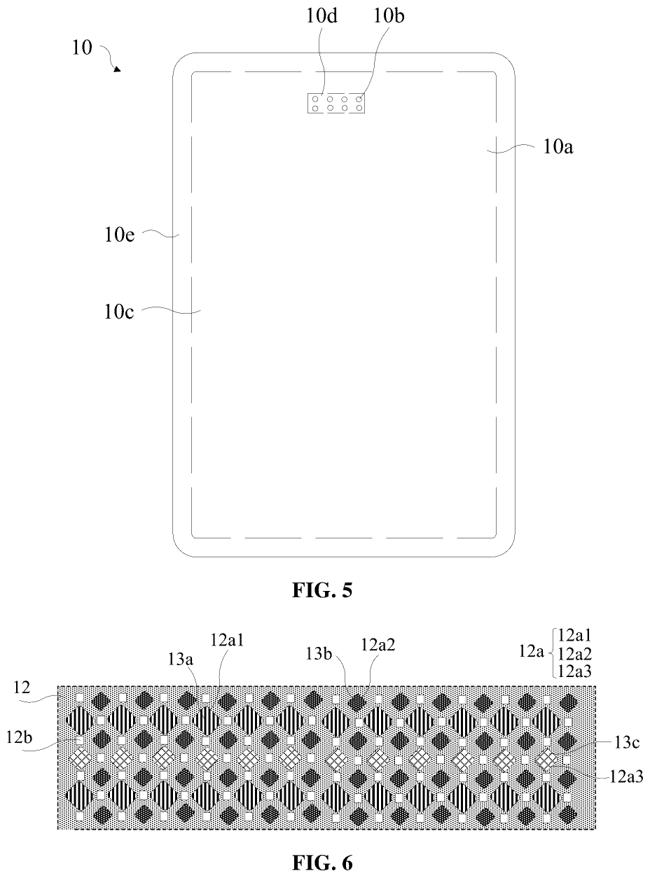

In some embodiments, referring to FIGS. 5 to 7, the display panel 10 includes a first display sub-region 10c and a second display sub-region 10d that are adjacent to each other, and the transmittance of the first display sub-region 10c is less than the transmittance of the second display sub-region 10d; the second display sub-region 10d is provided with multiple second regions 10b spaced apart, and the remaining regions of the second display sub-region 10d excluding the multiple second regions 10b and all the regions of the first display sub-region 10c, form the first region 10a.

The isolation structure 12 includes multiple second light-transmissive holes 12b disposed in one-to-one correspondence in the multiple second regions 10b. The protective layer 14 includes multiple protective sub-layers in one-to-one correspondence with the multiple second light-transmissive holes 12b. Each protective sub-layer covers the sidewall of a respective second light-transmissive hole 12b. It is to be understood that the sidewall of the isolation structure 12 that forms the multiple second light-transmittance holes 12b by enclosure includes the sidewalls of the multiple second light-transmissive holes 12b.

In some embodiments shown in FIGS. 5 and 6, a region in which the multiple second light-transmissive holes 12b are disposed is the first region 10a. Each protective sub-layer is equivalent to a single protective structure and protects the sidewall of the respective second light-transmissive hole 12b. It is to be understood that each protective sub-layer may have the same structure as the protective layer 14 described in detail below.

In some embodiments, the first display sub-region 10c is around the periphery of the second display sub-region 10d. It is to be understood that the first display sub-region 10c and the second display sub-region 10d jointly form the display region of the display panel 10.

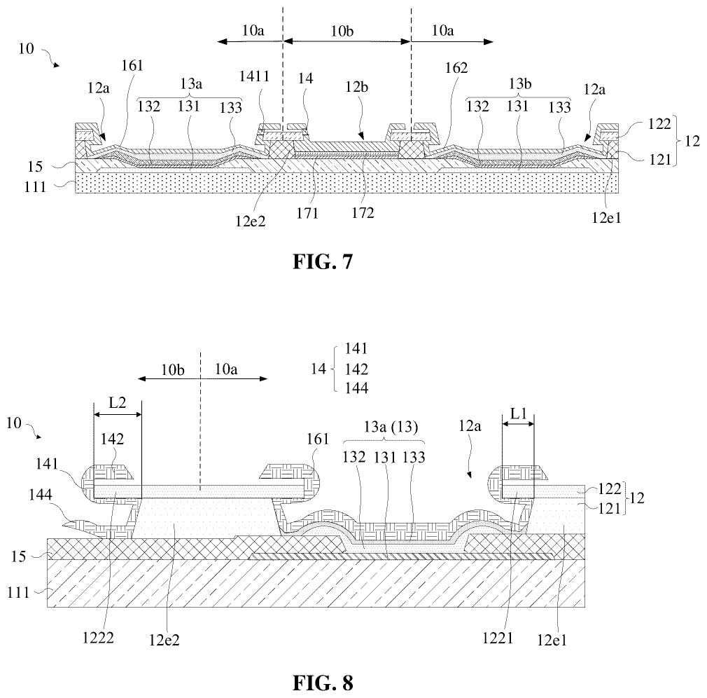

In some embodiments, referring to FIGS. 7 and 8, the isolation structure 12 includes a conductive portion 121 and a blocking portion 122 that are stacked in the direction facing away from the substrate 111, and the outer contour of the orthographic projection of the blocking portion 122 on the substrate 111 is located at the periphery of the outer contour of the orthographic projection of the conductive portion 121 on the substrate 121. A light-emitting element 13 includes a first electrode 131, a light-emitting portion 132, and a second electrode 133 that are stacked in the direction facing away from the substrate 111. The second electrode 133 is electrically connected to the conductive portion 121.

It is to be understood that the isolation structure 12 may be electrically connected to a pixel circuit in the display panel 10. In the embodiments of the present application, this is equivalent to that the second electrode 133 of the light-emitting element is connected to the pixel circuit through the isolation structure 12. In this manner, wires 1121 within the display region 10f of the display panel 10 are arranged more optimally.

It is to be noted that the first electrode 131 may be an anode, the second electrode 133 may be a cathode, and the light-emitting portion 132 at least includes an emission layer (EML). In addition, the light-emitting portion 132 may further include one or more of a hole injection layer (HIL), a hole transport layer (HTL), an electron injection layer (EIL), an electron transport layer (ETL), a hole blocking layer (HBL), or an electron blocking layer (EBL). Alternatively, the light-emitting portion 132 may also be a stacked light-emitting structure, that is, including at least two emission layers and a charge generation layer (CGL) located between adjacent emission layers. It is to be understood that light-emitting portions 132 of the multiple light-emitting elements 13 of different colors have different emission layers.

In some embodiments, the conductive portion 121 includes at least one metal layer. For example, the conductive portion 121 includes one metal layer. Further, the material of the conductive portion 121 includes at least one of metal or metal oxide. Exemplarily, the metal may be silver, copper, titanium, aluminum, or the like. The metal oxide may be tin oxide, zinc oxide, cadmium oxide, indium oxide, indium tin oxide, zinc indium oxide, zinc gallium oxide, zinc aluminum oxide, titanium tantalum oxide, or the like.

In some embodiments, the protective layer 14 at least covers at least part of the wall surface of the conductive portion 121 of the second isolation structure 12e2 facing the second region 10b. In this manner, the conductive portion 121 is protected to prevent the conductive portion 121 from being eroded.

In a specific embodiment, the conductive portion 121 includes aluminum. In the related art, when the isolation structure 12 is side-etched, silver ions of a cathode are replaced with aluminum, and precipitated silver ions adhere to the conductive portion 121. In the subsequent cleaning process, the precipitated silver ions are washed into an anode region in which the isolation structure 12 is exposed to form a dark spot region. In addition, in the subsequent process of manufacturing the multiple light-emitting elements 13, these ions are doped into the multiple light-emitting elements 13 to affect the light-emitting performance and service life of the multiple light-emitting elements 13, resulting in poor display. In the embodiments of the present application, the protective layer 14 protects the sidewall of the conductive portion 121 so that the silver ions are prevented from being precipitated due to the erosion of the conductive portion 121 by the etching solution.

In some embodiments, the material of the blocking portion 122 includes titanium or molybdenum.

In some embodiments, referring to FIGS. 8 and 9, the protective layer 14 further covers the wall surface of the blocking portion 122 of the second isolation structure 12e2 facing the second region 10b. In this manner, the contact area between the protective layer 14 and the second isolation structure 12e2 is enlarged so that the connection stability of the protective layer 14 is improved.

In some embodiments, the protective layer 14 includes a main body 141 covering the at least part of the sidewall of the second isolation structure 12e2 facing the second region 10b. Specifically, the main body 141 covers the wall surface of the blocking portion 122 of the second isolation structure 12e2 facing the second region 10b and the wall surface of the conductive portion 121 of the second isolation structure 12e2 facing the second region 10b.

In some embodiments, the material of the protective layer 14 is an organic material or an inorganic material. In this manner, the protective layer 14 has better protective performance.

In some embodiments, referring to FIG. 8, the protective layer 14 further includes a first extension portion 142 connected to the main body 141 and disposed on one side of the blocking portion 122 facing away from the substrate 111. The surface of one side of the first extension portion 142 facing the substrate 111 is spaced from the surface of the side of the blocking portion 122 facing away from the substrate 111. In this manner, this helps to reduce the risk of peeling the protective layer 14 and improve the connection stability of the protective layer 14.

It is to be understood that an organic material may be filled between the first extension portion 142 and the blocking portion 122. In this manner, this helps to enlarge the contact area between the protective layer 14 and other films in the display panel 10 and further improve the connection stability of the protective layer 14.

In some embodiments, referring to FIG. 9, the second isolation structure 12e2 is provided with a first trench 12d disposed on one side of the isolation structure 12 facing away from the substrate 111; the protective layer 14 further includes a second extension portion 143 connected to one end of the first extension portion 142 facing away from the main body 141 and covering at least part of the trench wall of the first trench 12d. In this manner, this helps to enlarge the contact area between the protective layer 14 and the isolation structure 12 and improve the connection stability of the protective layer 14.

In some embodiments, the first trench 12d includes a first sub-trench 12d2 and a first opening portion 12d1; the first opening portion 12d1 is located on one side of the first sub-trench 12d2 facing away from the substrate 111; the orthographic projection of the first opening portion 12d1 on the substrate 111 falls within the range of the orthographic projection of the first sub-trench 12d2 on the substrate 111. That is, the first trench 12d has a trench structure with “a small opening and a large cavity”. The second extension portion 143 covers at least part of the trench wall of the first sub-trench 12d2. In this manner, the first trench 12d is equivalent to a “sealing structure”. For one aspect, the contact area between the protective layer 14 and the isolation structure 12 is enlarged; for another aspect, even if the protective layer 14 undergoes peeling, the first opening portion 12d1 plays a blocking role to slow down the outward “lifting” of the protective layer 14 located within the first sub-trench 12d2 so that the protective layer 14 is “locked”, thereby reducing the risk of peeling the protective layer 14 and the isolation structure 12.

In some embodiments, the first opening portion 12d1 passes through the blocking portion 122 in the thickness direction of the substrate 111, and the first sub-trench 12d2 is disposed on the surface of one side of the conductive portion 121 facing away from the substrate 111. In this manner, this helps to form the first trench 12d by utilizing the difference in the materials of the blocking portion 122 and the conductive portion 121.

In some embodiments, the size of the first opening portion 12d1 in the first direction is less than the size of the first sub-trench 12d2 in the first direction; the first direction is perpendicular to the thickness direction of the substrate 111 and the extension direction of the first trench 12d. Referring to FIG. 9, the first direction is a horizontal direction, and the first trench 12d extends in the direction perpendicular to the paper surface.

In some embodiments, a light-emitting material film 171 and an electrode material layer 172 are stacked between the first extension portion 142 and the blocking portion 122, and the light-emitting material film 171 is located between the blocking portion 122 and the electrode material layer 172. It is to be noted that the light-emitting material film 171 may be disposed in the same layer and made of the same material as one of a first light-emitting material layer 173 of a first light-emitting element 13a, a second light-emitting material layer 174 of a second light-emitting element 13b, or a third light-emitting material layer of a third light-emitting element 13c, and correspondingly, the electrode material layer 172 is disposed in the same layer and made of the same material as an electrode material layer 172 of the first light-emitting element 13a, an electrode material layer 172 of the second light-emitting element 13b, or an electrode material layer 172 of the third light-emitting element 13c.

In some embodiments, referring to FIGS. 8 and 9, the protective layer 14 further includes a coverage portion 144 connected to the main body 141; one end of the coverage portion 144 is connected to one end of the main body 141 facing away from the blocking portion 122, and another end of the coverage portion 144 extends in the direction facing away from the second isolation structure 12e2. The coverage portion 144 is disposed so that the contact area between the protective layer 14 and the other films in the display panel 10 is enlarged, and the connection stability of the protective layer 14 is further improved.

In some embodiments, the display panel 10 further includes an insulating structure 15 disposed between the isolation structure 12 and the substrate 111.

In some embodiments, at least part of the surface of one side of the coverage portion 144 facing the substrate 111 is spaced from the surface of one side of the insulating structure 15 facing away from the substrate 111. Specifically, one end of the coverage portion 144 facing away from the main body 141 is lifted toward the direction facing away from the substrate 111.

It is to be noted that the morphology of the coverage portion 144 is related to the manufacturing process of the protective layer 14, and the coverage portion 144 is lifted because the light-emitting material film 171 and the electrode material layer 172 are covered below the coverage portion 144 and removed in the subsequent manufacturing process.

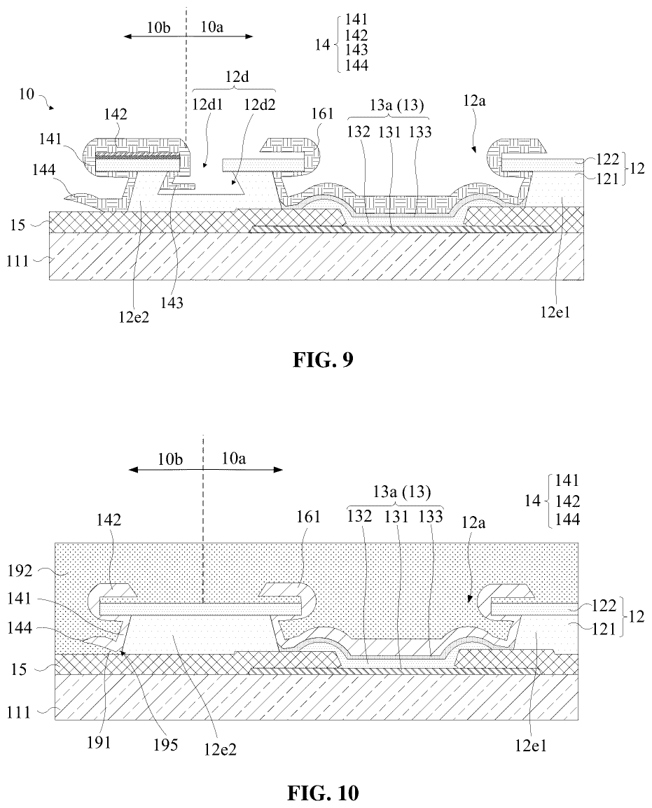

In some embodiments, referring to FIG. 10, a first gap 195 is present between the end of the main body 141 facing away from the blocking portion 122 and the sidewall of one side of the second isolation structure 12e2 facing the second region 10b. The entire surface of the side of the coverage portion 144 facing the substrate 111 is spaced from the surface of the side of the insulating structure 15 facing away from the substrate 111.

It is to be noted that the first gap 195 is present between the main body 141 and the sidewall of the second isolation structure 12e2 because the edge of the electrode material layer 172 climbs onto the sidewall of the second isolation structure 12e2, and the electrode material layer 172 is removed in the subsequent manufacturing process.

In some embodiments, the display panel 10 further includes a filling layer 191. At least part of the filling layer 191 is filled in the first gap 195 and filled between the coverage portion 144 and the insulating structure 15. The filling layer 191 is disposed so that the contact area between the protective layer 14 and films in the display panel 10 is enlarged, the connection stability of the protective layer 14 is further improved, and the sealing effect of the sidewall of the second isolation structure 12e2 is also enhanced.

In some embodiments, the filling layer 191 includes an organic material. In this manner, the filling layer 191 is ensured to be better filled in the first gap 195.

In some embodiments, the display panel 10 further includes an organic encapsulation layer 192 disposed on sides of the multiple light-emitting elements 13 facing away from the substrate 111 and the side of the isolation structure 12 facing away from the substrate 111; the filling layer 191 is disposed in the same layer and made of the same material as the organic encapsulation layer 192. In this manner, the filling layer 191 and the organic encapsulation layer 192 are simultaneously manufactured in the same manufacturing process so that the manufacturing process of the display panel 10 is reduced, and the manufacturing cost is reduced.

In some embodiments, referring to FIG. 8, one end of the coverage portion 144 facing the main body 141 contacts the surface of one side of the insulating structure 15 facing away from the substrate 111; the end of the coverage portion 144 facing away from the main body 141 is spaced from the insulating structure 15.

The coverage portion 144 contacts the insulating structure 15 so that the connection binding force of the protective layer 14 is improved, thereby preventing the protective layer 14 from undergoing peeling.

In some embodiments, the main body 141 covers the entire sidewall of the second isolation structure 12e2 facing the second region 10b. In this manner, this helps to enlarge the contact area between the protective layer 14 and the isolation structure 12 and improve the connection stability of the protective layer 14.

In some embodiments, one end of the blocking portion 122 facing a corresponding first isolation opening 12a extends towards the center of the corresponding first isolation opening 12a and protrudes from the wall surface of one side of the conductive portion 121 facing the corresponding first isolation opening 12a; one end of the blocking portion 122 facing the second region 10b extends towards the second region 10b and protrudes from the wall surface of one side of the conductive portion 121 facing the second region 10b.

A portion of the blocking portion 122 protruding from the wall surface of the side of the conductive portion 121 facing the corresponding first isolation opening 12a is a first blocking sub-portion 1221, and the first blocking sub-portion 1221 protrudes from the wall surface of the conductive portion 121 by a first length L1; a portion of the blocking portion 122 protruding from the wall surface of the side of the conductive portion 121 facing the second region 10b is a second blocking sub-portion 1222, and the second blocking sub-portion 1222 protrudes from the wall surface of the conductive portion 121 by a second length L2; the second length L2 is greater than the first length L1.

In this manner, in the process of evaporating the light-emitting material film 171 and the electrode material layer 172, the second blocking sub-portion 1222 has a large blocking area so that the insulating structure 15 below the second blocking sub-region 1222 is not covered by the light-emitting material film 171 and the electrode material layer 172, thereby making the coverage portion 144 contact the insulating structure 15.

In some embodiments, the ratio of the second length L2 to the first length L1 ranges from 1 to 3. Exemplarily, the ratio of the second length L2 to the first length L1 may be 1, 1.5, 2, 3, or between any two of the preceding values. In this manner, the manufacturing cost is not particularly high on the premise that the second blocking sub-region 1222 has a relatively moderate blocking area.

In some embodiments, the isolation structure 12 is a metal structure, and the density of the metal structure of the first region 10a is greater than the density of the metal structure of the second region 10b. In this manner, when the isolation structure 12 is side-etched, the side-etching depth of the side of the second isolation structure 12e2 facing the second region 10b is deeper than the side-etching depth at the first isolation opening 12a, that is, the protruding length of the second blocking sub-portion 1222 is longer than the protruding length of the first blocking sub-portion 1221.

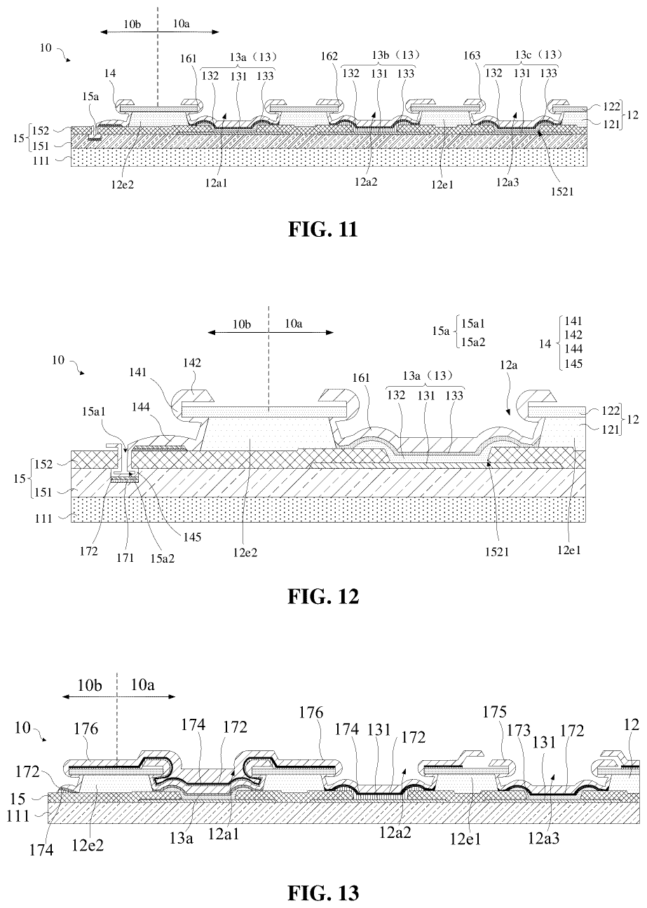

In some embodiments, referring to FIGS. 11 and 12, the insulating structure 15 located in the second region 10b is provided with a second trench 15a, the protective layer 14 further includes a third extension portion 145, and the third extension portion 145 is connected to the end of the coverage portion 144 facing away from the main body 141 and covers at least part of the trench wall of the second trench 15a. In this manner, this helps to enlarge the contact area between the protective layer 14 and the insulating structure 15 and improve the connection stability of the protective layer 14.

In some embodiments, the second trench 15a includes a second sub-trench 15a2 and a second opening portion 15a1; the second opening portion 15a1 is located on one side of the second sub-trench 15a2 facing away from the substrate 111; the orthographic projection of the second opening portion 15a1 on the substrate 111 falls within the orthographic projection of the second sub-trench 15a2 on the substrate 111. That is, the second trench 15a has a trench structure with “a small opening and a large cavity”.

Specifically, the third extension portion 145 covers at least part of the trench wall of the second sub-trench 15a2.

In this manner, the second trench 15a is equivalent to a “sealing structure”. For one aspect, the contact area between the protective layer 14 and the insulating structure 15 is enlarged; for another aspect, even if the protective layer 14 undergoes peeling, the second opening portion 15a1 plays a blocking role to slow down the outward “lifting” of the protective layer 14 located within the second sub-trench 15a2 so that the protective layer 14 is “locked”, thereby reducing the risk of peeling the protective layer 14.

In some embodiments, the insulating structure 15 includes a planarization layer 151 and a pixel defining layer 152 that are stacked, and the planarization layer 151 is disposed between the substrate 111 and the pixel defining layer 152; the second opening portion 15a1 passes through the pixel defining layer 152 in the thickness direction of the substrate 111, and the second sub-trench 15a2 is disposed on the surface of one side of the planarization layer 151 facing away from the substrate 111. In this manner, this helps to form the second trench 15a by utilizing the difference in the materials of the planarization layer 151 and the pixel defining layer 152.

In some embodiments, the size of the second opening portion 15a1 in the second direction is less than the size of the second sub-trench 15a2 in the second direction; the second direction is perpendicular to the thickness direction of the substrate 111 and the extension direction of the second trench 15a. Referring to FIG. 12, the second direction is a horizontal direction, and the second trench 15a extends in the direction perpendicular to the paper surface.

In some embodiments, a light-emitting material film 171 and an electrode material layer 172 are stacked between the coverage portion 144 and the insulating structure 15, and the light-emitting material film 171 is located between the insulating structure 15 and the electrode material layer 172.

In some embodiments, the pixel defining layer 152 is provided with multiple pixel openings 1521. The multiple first isolation openings 12a pass through the multiple pixel openings 1521 respectively. The multiple light-emitting elements 13 correspond to the multiple pixel openings 1521 respectively. Exemplarily, the multiple first isolation openings 12a pass through the multiple pixel openings 1521 in one-to-one correspondence, and the multiple light-emitting elements 13 are in one-to-one correspondence with the multiple pixel openings.

In some embodiments, the multiple light-emitting elements 13 include multiple first light-emitting elements 13a, multiple second light-emitting elements 13b and multiple third light-emitting elements 13c; the multiple first light-emitting elements 13a, the multiple second light-emitting elements 13b and the multiple third light-emitting elements 13c are configured to emit light of different colors respectively. The display panel 10 further includes multiple first encapsulation portions 161, multiple second encapsulation portions 162 and multiple third encapsulation portions 163; the multiple first encapsulation portions 161 are in one-to-one correspondence with the multiple first light-emitting elements 13a, and a first encapsulation portion 161 is disposed on one side of a corresponding first light-emitting element 13a facing away from the substrate 111; the multiple second encapsulation portions 162 are in one-to-one correspondence with the multiple second light-emitting elements 13b, and a second encapsulation portion 162 is disposed on one side of a corresponding second light-emitting element 13b facing away from the substrate 111; the multiple third encapsulation portions 163 are in one-to-one correspondence with the multiple third light-emitting elements 13c, and a third encapsulation portion 163 is disposed on one side of a corresponding third light-emitting element 13c facing away from the substrate 111.

Specifically, the multiple first isolation openings 12a include multiple first openings 12a1, multiple second openings 12a2 and multiple third openings 12a3; at least part of a first light-emitting element 13a is disposed within a first opening 12a1; at least part of a second light-emitting element 13b is disposed within a second opening 12a2; at least part of a third light-emitting element 13c is disposed within a third opening 12a3.

In some embodiments, the first encapsulation portion 161, the second encapsulation portion 162 and the third encapsulation portion 163 are all inorganic films. In this manner, the first encapsulation portion 161, the second encapsulation portion 162 and the third encapsulation portion 163 have better encapsulation performance.

In some embodiments, any one of the first encapsulation portion 161, the second encapsulation portion 162, or the third encapsulation portion 163 is disposed in the same layer and made of the same material as the protective layer 14. In this manner, this is equivalent to that the protective layer 14 and an encapsulation portion (one of the three encapsulation portions) are manufactured in the same manufacturing process so that the manufacturing process of the display panel 10 is reduced, and the manufacturing cost is reduced.

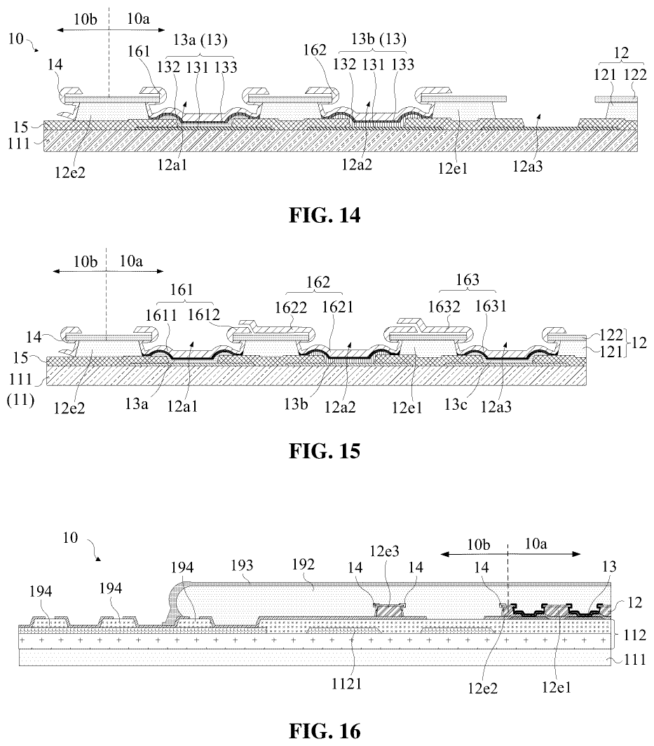

In a specific example, referring to FIGS. 13 and 14, the multiple first light-emitting elements 13a and the multiple first encapsulation portions 161 are manufactured first, the multiple second light-emitting elements 13b and the multiple second encapsulation portions 162 are manufactured subsequently, and the multiple third light-emitting elements 13c and the multiple third encapsulation portions 163 are manufactured lastly. In the process of manufacturing the multiple second encapsulation portions 162, a second light-emitting material layer 174, the electrode material layer 172 and a second encapsulation material layer 176 not only cover the multiple first openings 12a1, the multiple second openings 12a2 and the multiple third openings 12a3 but also cover the isolation structure 12. Further, the second encapsulation material layer 176 further covers the sidewall of the second isolation structure 12e2 facing the second region 10b. The second light-emitting material layer 174, the electrode material layer 172 and the second encapsulation material layer 176 within the multiple third openings 12a3 are etched to form a structure as shown in FIG. 13. The second light-emitting material layer 174, the electrode material layer 172 and the second encapsulation material layer 176 within the multiple first openings 12a1 as well as a first light-emitting material layer 173, the electrode material layer 172 and a first encapsulation material layer 175 within the multiple third openings 12a3 are etched subsequently, and the second encapsulation material layer 176 on the sidewall of the second isolation structure 12e2 is retained, thereby forming the protective layer 14.

In some embodiments, referring to FIG. 15, the first encapsulation portion 161 includes a first main portion 1611 and a first sub-portion 1612 connected to the first main portion 1611; the first main portion 1611 covers the first light-emitting element 13a and the sidewall of a corresponding first isolation opening 12a; the first sub-portion 1612 is disposed on the side of the isolation structure 12 facing away from the substrate 111. In this manner, the contact area between the first encapsulation portion 161 and the films in the display panel 10 is enlarged, and the connection stability of the first encapsulation portion 161 is improved.

In some embodiments, the first sub-portion 1612 is spaced from the surface of the side of the isolation structure 12 facing away from the substrate 111, because in the process of manufacturing the first light-emitting element 13a, the first light-emitting material layer 173 and the electrode material layer 172 are formed between the first sub-portion 1612 and the isolation structure 12, and in subsequent steps, the first light-emitting material layer 173 and the electrode material layer 172 in this region are removed.

In some embodiments, the second encapsulation portion 162 includes a second main portion 1621 and a second sub-portion 1622 connected to the second main portion 1621; the second main portion 1621 covers the second light-emitting element 13b and the sidewall of a corresponding first isolation opening 12a; the second sub-portion 1622 is disposed on the side of the isolation structure 12 facing away from the substrate 111. In this manner, the contact area between the second encapsulation portion 162 and the films in the display panel 10 is enlarged, and the connection stability of the second encapsulation portion 162 is improved.

In some embodiments, the second sub-portion 1622 is spaced from the surface of the side of the isolation structure 12 facing away from the substrate 111, because in the process of manufacturing the second light-emitting element 13b, the second light-emitting material layer 174 and the electrode material layer 172 are formed between the second sub-portion 1622 and the isolation structure 12, and in subsequent steps, the second light-emitting material layer 174 and the electrode material layer 172 in this region are removed.

In some embodiments, the third encapsulation portion 163 includes a third main portion 1631 and a third sub-portion 1632 connected to the third main portion 1631; the third main portion 1631 covers the third light-emitting element 13c and the sidewall of a corresponding first isolation opening 12a; the third sub-portion 1632 is disposed on the side of the isolation structure 12 facing away from the substrate 111. In this manner, the contact area between the third encapsulation portion 163 and the films in the display panel 10 is enlarged, and the connection stability of the third encapsulation portion 163 is improved.

In some embodiments, the third sub-portion 1632 is spaced from the surface of the side of the isolation structure 12 facing away from the substrate 111, because in the process of manufacturing the third light-emitting element 13c, the third light-emitting material layer and the electrode material layer 172 are formed between the third sub-portion 1632 and the isolation structure 12, and in subsequent steps, the third light-emitting material layer and the electrode material layer 172 in this region are removed.

In some embodiments, in adjacent first encapsulation portion 161 and second encapsulation portion 162, the orthographic projection of the first sub-portion 1612 on the substrate 111 overlaps the orthographic projection of the second sub-portion 1622 on the substrate 111. In this manner, this is equivalent to that the first encapsulation portion 161 overlaps the second encapsulation portion 162 in the thickness direction of the display panel 10 so that the probability of peeling the first encapsulation portion 161 or the second encapsulation portion 162 is reduced, and the encapsulation reliability of the first encapsulation portion 161 or the second encapsulation portion 162 is improved.

In some embodiments, in the adjacent first encapsulation portion 161 and second encapsulation portion 162, the first sub-portion 1612 and the second sub-portion 1622 are spaced apart.

In some embodiments, in the adjacent first encapsulation portion 161 and second encapsulation portion 162, a part of the second sub-portion 1622 is located on one side of the first sub-portion 1612 facing away from the substrate 111. In this manner, the second sub-portion 1622 blocks the first sub-portion 1612 above the first sub-portion 1612 to prevent the first sub-portion 1612 from being lifted and undergoing peeling, thereby improving the encapsulation reliability of the first encapsulation portion 161.

In some embodiments, in adjacent second encapsulation portion 162 and third encapsulation portion 163, the orthographic projection of the second sub-portion 1622 on the substrate 111 overlaps the orthographic projection of the third sub-portion 1632 on the substrate 111. In this manner, this is equivalent to that the second encapsulation portion 162 overlaps the third encapsulation portion 163 in the thickness direction of the display panel 10 so that the probability of peeling the second encapsulation portion 162 or the third encapsulation portion 163 is reduced, and the encapsulation reliability of the second encapsulation portion 162 or the third encapsulation portion 163 is improved.

In some embodiments, in the adjacent second encapsulation portion 162 and third encapsulation portion 163, the second sub-portion 1622 and the third sub-portion 1632 are spaced apart.

In some embodiments, in the adjacent second encapsulation portion 162 and third encapsulation portion 163, a part of the third sub-portion 1632 is located on one side of the second sub-portion 1622 facing away from the substrate 111. In this manner, the third sub-portion 1632 blocks the second sub-portion 1622 above the second sub-portion 1622 to prevent the second sub-portion 1622 from being lifted and undergoing peeling, thereby improving the encapsulation reliability of the second encapsulation portion 162.

In some embodiments, referring to FIG. 16, the insolation structure 12 further includes a third isolation structure 12e3 located in the bezel region 10e and electrically connected to the first isolation structure 12e1. The display panel 10 further includes an array film 112 disposed between the substrate 111 and the isolation structure 12; the third isolation structure 12e3 is electrically connected to wires 1121 in the array film 112. In this manner, the third isolation structure 12e3 also serves as the wires 1121 so that the manufacturing process of the display panel 10 is reduced, and the manufacturing cost is reduced.

It is to be understood that the third isolation structure 12e3 may be electrically connected to the first isolation structure 12e1 directly or through another component. For example, the first isolation structure 12e1 is electrically connected to the third isolation structure 12e3 through the second isolation structure 12e2. Further, the first isolation structure 12e1, the second isolation structure 12e2 and the third isolation structure 12e3 may be located in the same layer so that the manufacturing cost is reduced. Furthermore, the third isolation structure 12e3 may be directly connected to the first isolation structure 12e1 or may also be spaced from the first isolation structure 12e1.

In some embodiments, the protective layer 14 further covers at least part of the sidewall of the third isolation structure 12e3. In this manner, in the process of manufacturing the display panel 10, the erosion of the sidewall of the third isolation structure 12e3 by the process solution (such as the etching solution) is weakened so that the light-emitting performance of the multiple light-emitting elements 13 is prevented from being affected due to the impact on the multiple light-emitting elements 13 caused by ion precipitation in the third isolation structure 12e3.

In some embodiments, the display panel 10 further includes dams 194 disposed in the bezel region 10e and around the periphery of the isolation structure 12. The dams 194 are disposed so that the organic material in the display region is prevented from overflowing.

In some embodiments, the display panel 10 further includes the organic encapsulation layer 192 disposed on the sides of the multiple light-emitting elements 13 facing away from the substrate 111 and the side of the isolation structure 12 facing away from the substrate 111.

In some embodiments, the organic encapsulation layer 192 also covers at least some dams 194.

In some embodiments, the display panel 10 further includes an inorganic encapsulation layer 193 at least covering one side of the organic encapsulation layer 192 facing away from the substrate 111.

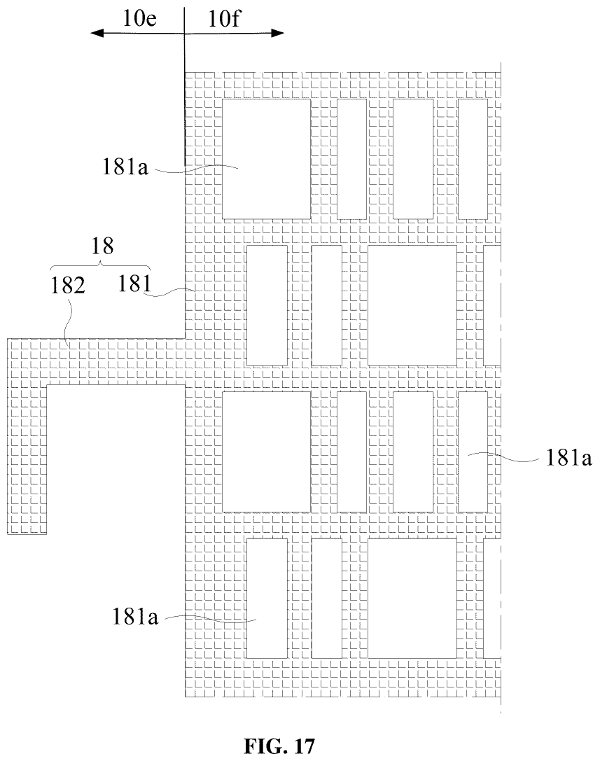

Another display panel 10 provided in embodiments of the present application is shown in FIGS. 17 to 20.

Specifically, the display panel 10 includes a display region 10f and a bezel region 10e that are adjacent to each other. The display panel 10 includes an array substrate 11, multiple light-emitting elements 13, a metal layer 18 and a protective layer 14. The multiple light-emitting elements 13 are spaced apart on one side of the array substrate 11. The metal structure 18 is disposed on the side of the array substrate 11 and includes a first portion 181 and a second portion 182 that are electrically connected. The first portion 181 is located in the display region 10f and configured to space apart adjacent light-emitting elements 13. The second portion 182 is located in the bezel region 10e and electrically connected to wires 1121 in the array substrate 11. The protective layer 14 at least covers at least part of the sidewall of the second portion 182. It is to be understood that the array substrate 11 may include a substrate 111 and an array film 112 disposed on the substrate 111, and the wires 1121 are disposed in the array film 112.

In the display panel 10 provided in the embodiments of the present application, the protective layer 14 is disposed to cover the at least part of the sidewall of the second portion 182 of the metal structure 18 so that the sidewall of the second portion 182 is protected. In this manner, in the process of manufacturing the display panel 10, the erosion of the sidewall of the second portion 182 by the process solution (such as the etching solution) is weakened so that the light-emitting performance of the multiple light-emitting elements 13 is prevented from being affected due to the impact on the multiple light-emitting elements 13 caused by ion precipitation in the second portion 182.

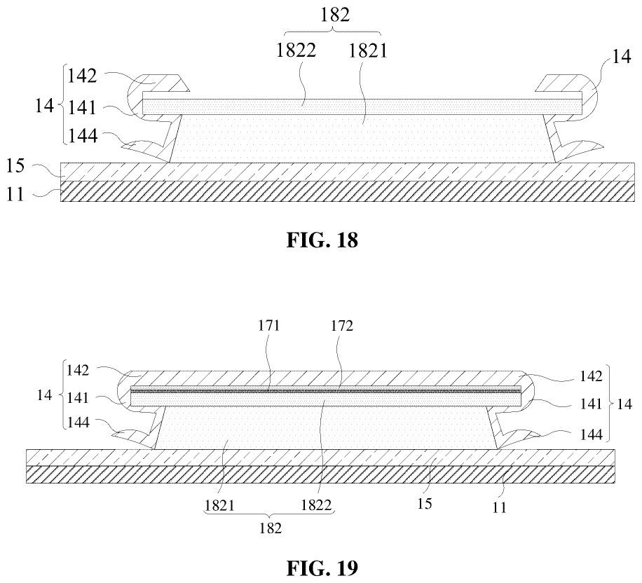

In some embodiments, referring to FIG. 18, the second portion 182 includes a first metal layer 1821 and a second metal layer 1822 that are stacked in the direction facing away from the array substrate 11; two opposite ends of the second metal layer 1822 in the first direction protrude from two opposite sides of the first metal layer 1821 in the first direction respectively. The sidewall of at least one side of the first metal layer 1821 in the first direction is covered with the protective layer 14. The first direction is perpendicular to the thickness direction of the array substrate 11 and the extension direction of the second portion 182. In FIG. 18, the first direction is a horizontal direction, and the extension direction of the second portion 182 is a direction perpendicular to the paper surface.

In some embodiments, the sidewalls of the two sides of the first metal layer 1821 in the first direction are covered with protective layers 14 respectively. In this manner, the erosion of the sidewall of the second portion 182 by the process solution (such as the etching solution) is further weakened.

In some embodiments, the protective layer 14 further covers the sidewall of the second metal layer 1822 in the first direction. In this manner, the contact area between the protective layer 14 and the second portion 182 is improved, and the connection stability of the protective layer 14 is improved.

In some embodiments, the protective layer 14 includes a main body 141 covering the sidewall of the first metal layer 1821 in the first direction and the sidewall of the second metal layer 1822 in the first direction.

In some embodiments, the material of the protective layer 14 is an organic material or an inorganic material. In this manner, the protective layer 14 has better protective performance.

In some embodiments, the protective layer 14 further includes a first extension portion 142 connected to the main body 141 and disposed on one side of the second metal layer 1822 facing away from the array substrate 11. The surface of one side of the first extension portion 142 facing the array substrate 11 is spaced from the surface of the side of the second metal layer 1822 facing away from the array substrate 11. In this manner, this helps to reduce the risk of peeling the protective layer 14 and improve the connection stability of the protective layer 14.

It is to be understood that an organic material may be filled between the first extension portion 142 and the second metal layer 1822. In this manner, this helps to enlarge the contact area between the protective layer 14 and other films in the display panel 10 and further improve the connection stability of the protective layer 14.

In some embodiments, referring to FIG. 19, first extension portions 142 of two protective layers 14 located on the two sides of the first metal layer 1821 in the first direction are connected to each other. In this manner, the two protective layers 14 are connected so that the protective layers 14 have better connection stability.

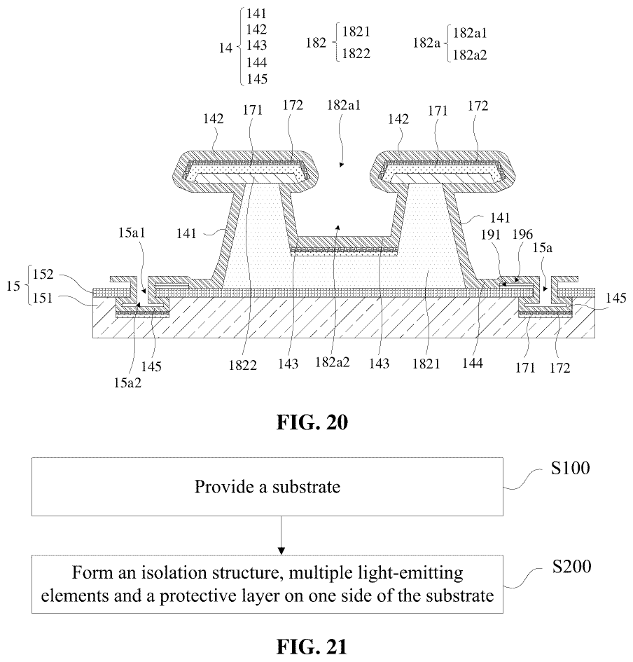

In some embodiments, referring to FIG. 20, the second portion 182 is provided with a third trench 182a disposed on one side of the second portion 182 facing away from the array substrate 11; the protective layer 14 further includes a second extension portion 143 connected to one end of the first extension portion 142 facing away from the main body 141 and covering at least part of the trench wall of the third trench 182a. In this manner, this helps to enlarge the contact area between the protective layer 14 and the second portion 182 and improve the connection stability of the protective layer 14.

In some embodiments, the third trench 182a includes a third sub-trench 182a2 and a third opening portion 182a1; the third opening portion 182a1 is located on one side of the third sub-trench 182a2 facing away from the array substrate 11; the orthographic projection of the third opening portion 182a1 on the array substrate 11 falls within the orthographic projection of the third sub-trench 182a2 on the array substrate 11. That is, the third trench 182a has a trench structure with “a small opening and a large cavity”. Specifically, the second extension portion 143 covers at least part of the trench wall of the third sub-trench 182a2. In this manner, the third trench 182a is equivalent to a “sealing structure”. For one aspect, the contact area between the protective layer 14 and the second portion 182 is enlarged; for another aspect, even if the protective layer 14 undergoes peeling, the third opening portion 182a1 plays a blocking role to slow down the outward “lifting” of the protective layer 14 located within the third sub-trench 182a2 so that the protective layer 14 is “locked”, thereby reducing the risk of peeling the protective layer 14 and the second portion 182.

In some embodiments, the third opening portion 182a1 passes through the second metal layer 1822 in the thickness direction of the array substrate 11, and the third sub-trench 182a2 is disposed on one side of the first metal layer 1821 facing away from the array substrate 11. In this manner, this helps to form the third trench 182a by utilizing the difference in the materials of the first metal layer 1821 and the second metal layer 1822.

In some embodiments, referring to FIG. 20, the size of the third opening portion 182a1 in the first direction is less than the size of the third sub-trench 182a2 in the first direction; the first direction is perpendicular to the thickness direction of the array substrate 11 and the extension direction of the third trench 182a. In FIG. 20, the first direction is a horizontal direction, and the third trench 182a extends in the direction perpendicular to the paper surface.

In some embodiments, a light-emitting material film 171 and an electrode material layer 172 are stacked between the first extension portion 142 and the second metal layer 1822, and the light-emitting material film 171 is located between the second metal layer 1822 and the electrode material layer 172. It is to be noted that the light-emitting material film 171 may be disposed in the same layer and made of the same material as one of a first light-emitting material layer 173 of a first light-emitting element 13a, a second light-emitting material layer 174 of a second light-emitting element 13b, or a third light-emitting material layer of a third light-emitting element 13c, and correspondingly, the electrode material layer 172 is disposed in the same layer and made of the same material as an electrode material layer 172 of the first light-emitting element 13a, an electrode material layer 172 of the second light-emitting element 13b, or an electrode material layer 172 of the third light-emitting element 13c.

In some embodiments, the protective layer 14 further includes a coverage portion 144 connected to the main body 141; one end of the coverage portion 144 is connected to one end of the main body 141 facing away from the second metal layer 1822, and another end of the coverage portion 144 extends in the direction facing away from the second portion 182. The coverage portion 144 is disposed so that the contact area between the protective layer 14 and the other films in the display panel 10 is enlarged, and the connection stability of the protective layer 14 is further improved.

In some embodiments, the display panel 10 further includes an insulating structure 15 disposed between the metal structure 18 and the array substrate 11.

In some embodiments, referring to FIGS. 18 and 19, at least part of the surface of one side of the coverage portion 144 facing the array substrate 11 is spaced from the surface of one side of the insulating structure 15 facing away from the array substrate 11. Specifically, one end of the coverage portion 144 facing away from the main body 141 is lifted toward the direction facing away from the array substrate 11.

It is to be noted that the morphology of the coverage portion 144 is related to the manufacturing process of the protective layer 14, and the coverage portion 144 is lifted because the light-emitting material film 171 and the electrode material layer 172 are covered below the coverage portion 144 and removed in the subsequent manufacturing process.

In some embodiments, a second gap 196 is present between the end of the main body 141 facing away from the second metal layer 1822 and the sidewall of the first metal layer 1821; the entire surface of the side of the coverage portion 144 facing the array substrate 11 is spaced from the surface of the side of the insulating structure 15 facing away from the array substrate 11. The first gap 195 in FIG. 10 is equivalent to the second gap 196 herein. The second gap 196 is present between the main body 141 and the sidewall of the second metal layer 1822 because the edge of the electrode material layer 172 climbs onto the sidewall of the second metal layer 1822, and the electrode material layer 172 is removed in the subsequent manufacturing process.

In some embodiments, the display panel 10 further includes a filling layer 191. At least part of the filling layer 191 is filled in the second gap and between the coverage portion 144 and the insulating structure 15. The filling layer 191 is disposed so that the contact area between the protective layer 14 and films in the display panel 10 is enlarged, and the connection stability of the protective layer 14 is further improved.

In some embodiments, the filling layer 191 includes an organic material. In this manner, the filling layer 191 is ensured to be better filled in the second gap.

In some embodiments, the display panel 10 further includes an organic encapsulation layer 192 disposed on sides of the multiple light-emitting elements 13 facing away from the array substrate 11 and one side of the metal structure 18 facing away from the array substrate 11; the filling layer 191 is disposed in the same layer and made of the same material as the organic encapsulation layer 192. In this manner, the filling layer 191 and the organic encapsulation layer 192 are simultaneously manufactured in the same manufacturing process so that the manufacturing process of the display panel 10 is reduced, and the manufacturing cost is reduced.

In some embodiments, the display panel 10 further includes dams 194 disposed in the bezel region 10e and around the periphery of the metal structure 18. The dams 194 are disposed so that the organic material in the display region 10f is prevented from overflowing.

In some embodiments, the display panel 10 further includes an inorganic encapsulation layer 193 at least covering one side of the organic encapsulation layer 192 facing away from the array substrate 11.

In some embodiments, one end of the coverage portion 144 facing the main body 141 contacts the surface of one side of the insulating structure 15 facing away from the array substrate 11; the end of the coverage portion 144 facing away from the main body 141 is spaced from the insulating structure 15.

The coverage portion 144 contacts the insulating structure 15 so that the connection binding force of the protective layer 14 can be improved, thereby preventing the protective layer 14 from undergoing peeling.

In some embodiments, the first portion 181 includes a third metal layer (which is not shown in the figures) and a fourth metal layer (which is not shown in the figures) that are stacked in the direction facing away from the array substrate 11; the first portion 181 is provided with multiple second isolation openings 181a, and the multiple light-emitting elements 13 correspond to the multiple second isolation openings 181a respectively; at least parts of the multiple light-emitting elements 13 are disposed within the corresponding multiple second isolation openings 181a respectively.

In some embodiments, one end of the fourth metal layer facing a corresponding second isolation opening 181a extends towards the center of the corresponding second isolation opening 181a and protrudes from the wall surface of one side of the third metal layer facing the second isolation opening 181a. The length of the fourth metal layer protruding from the wall surface of the side of the third metal layer facing the second isolation opening 181a is the first length; the length of the first metal layer 1821 protruding from the wall surface of one side of the second metal layer 1822 in the first direction is the second length; the second length is greater than the first length.

With the preceding configuration, in the process of evaporating the light-emitting material film 171 and the electrode material layer 172, the second metal layer 1822 has a large blocking area so that the insulating structure 15 below the second metal layer 1822 is not covered by the light-emitting material film 171 and the electrode material layer 172, thereby making the coverage portion 144 contact the insulating structure 15.

In some embodiments, the ratio of the second length to the first length ranges from 1 to 3. Exemplarily, the ratio of the second length to the first length may be 1, 1.5, 2, 3, or between any two of the preceding values. In this manner, the manufacturing cost cannot be particularly high on the premise that the second metal layer 1822 has a relatively moderate blocking area.

In some embodiments, the first metal layer 1821 is disposed in the same layer and made of the same material as the third metal layer. Exemplarily, the material of the first metal layer 1821 and the third metal layer may be aluminum.

In some embodiments, the second metal layer 1822 is disposed in the same layer and made of the same material as the fourth metal layer. Exemplarily, the material of the second metal layer 1822 and the fourth metal layer may be titanium or molybdenum.

In some embodiments, the density of the metal structure 18 in the display region 10f is greater than the density of the metal structure 18 in the bezel region 10e. In this manner, when the metal structure 18 is side-etched, the side-etching depth of the second portion 182 is deeper than the side-etching depth of the first portion 181, that is, the protruding length of the second metal layer 1822 is longer than the protruding length of the fourth metal layer.

In some embodiments, the insulating structure 15 located in the bezel region 10e is provided with a second trench 15a, and the protective layer 14 further includes a third extension portion 145 connected to the end of the coverage portion 144 facing away from the main body 141 and covering at least part of the trench wall of the second trench 15a. In this manner, this helps to enlarge the contact area between the protective layer 14 and the insulating structure 15 and improve the connection stability of the protective layer 14.

In some embodiments, the second trench 15a includes a second sub-trench 15a2 and a second opening portion 15a1; the second opening portion 15a1 is located on one side of the second sub-trench 15a2 facing away from the array substrate 11; the orthographic projection of the second opening portion 15a1 on the array substrate 11 falls within the orthographic projection of the second sub-trench 15a2 on the array substrate 11. That is, the second trench 15a has a trench structure with “a small opening and a large cavity”. Specifically, the third extension portion 145 covers at least part of the trench wall of the second sub-trench 15a2.

In some embodiments, the insulating structure 15 includes a planarization layer 151 and a pixel defining layer 152 that are stacked, and the planarization layer 151 is disposed between the array substrate 11 and the pixel defining layer 152; the second opening portion 15a1 passes through the pixel defining layer 152 in the thickness direction of the array substrate 11, and the second sub-trench 15a2 is disposed on the surface of one side of the planarization layer 151 facing away from the array substrate 11. In this manner, this helps to form the second trench 15a by utilizing the difference in the materials of the planarization layer 151 and the pixel defining layer 152.

In some embodiments, the size of the second opening portion 15a1 in the second direction is less than the size of the second sub-trench 15a2 in the second direction; the second direction is perpendicular to the thickness direction of the array substrate 11 and the extension direction of the second trench 15a. Referring to FIG. 20, the second direction is a horizontal direction, and the second trench 15a extends in the direction perpendicular to the paper surface.

In some embodiments, a light-emitting material film 171 and an electrode material layer 172 are stacked between the coverage portion 144 and the insulating structure 15, and the light-emitting material film 171 is located between the insulating structure 15 and the electrode material layer 172.

In some embodiments, the multiple second isolation openings 181a pass through multiple pixel openings respectively. Exemplarily, the multiple second isolation openings 181a pass through the multiple pixel openings in one-to-one correspondence, and the multiple light-emitting elements 13 are in one-to-one correspondence with the multiple pixel openings.

In some embodiments, the multiple light-emitting elements 13 include multiple first light-emitting elements 13a, multiple second light-emitting elements 13b and multiple third light-emitting elements 13c; the multiple first light-emitting elements 13a, the multiple second light-emitting elements 13b and the multiple third light-emitting elements 13c are configured to emit light of different colors respectively and disposed in one-to-one correspondence at the multiple second isolation openings 181a. The display panel 10 further includes multiple first encapsulation portions 161, multiple second encapsulation portions 162 and multiple third encapsulation portions 163; the multiple first encapsulation portions 161 are in one-to-one correspondence with the multiple first light-emitting elements 13a, and a first encapsulation portion 161 is disposed on one side of a corresponding first light-emitting element 13a facing away from the array substrate 11; the multiple second encapsulation portions 162 are in one-to-one correspondence with the multiple second light-emitting elements 13b, and a second encapsulation portion 162 is disposed on one side of a corresponding second light-emitting element 13b facing away from the array substrate 11; the multiple third encapsulation portions 163 are in one-to-one correspondence with the multiple third light-emitting elements 13c, and a third encapsulation portion 163 is disposed on one side of a corresponding third light-emitting element 13c facing away from the array substrate 11.

In some embodiments, referring to FIG. 15, the first encapsulation portion 161 includes a first main portion 1611 and a first sub-portion 1612 connected to the first main portion 1611; the first main portion 1611 covers the first light-emitting element 13a and the sidewall of a corresponding second isolation opening 181a; the first sub-portion 1612 is disposed on the side of the metal structure 18 facing away from the array substrate 11. In this manner, the contact area between the first encapsulation portion 161 and the films in the display panel 10 is enlarged, and the connection stability of the first encapsulation portion 161 is improved.

In some embodiments, the first sub-portion 1612 is spaced from the surface of the side of the metal structure 18 facing away from the array substrate 11 because in the process of manufacturing the first light-emitting element 13a, the first light-emitting material layer 173 and the electrode material layer 172 are formed between the first sub-portion 1612 and the metal structure 18, and in subsequent steps, the first light-emitting material layer 173 and the electrode material layer 172 in this region are removed.

In some embodiments, the second encapsulation portion 162 includes a second main portion 1621 and a second sub-portion 1622 connected to the second main portion 1621; the second main portion 1621 covers the second light-emitting element 13b and the sidewall of a corresponding second isolation opening 181a; the second sub-portion 1622 is disposed on the side of the metal structure 18 facing away from the array substrate 11. In this manner, the contact area between the second encapsulation portion 162 and the films in the display panel 10 is enlarged, and the connection stability of the second encapsulation portion 162 is improved.

In some embodiments, the second sub-portion 1622 is spaced from the surface of the side of the metal structure 18 facing away from the array substrate 11 because in the process of manufacturing the second light-emitting element 13b, the second light-emitting material layer 174 and the electrode material layer 172 are formed between the second sub-portion 1622 and the metal structure 18, and in subsequent steps, the second light-emitting material layer 174 and the electrode material layer 172 in this region are removed.

In some embodiments, the third encapsulation portion 163 includes a third main portion 1631 and a third sub-portion 1632 connected to the third main portion 1631; the third main portion 1631 covers the third light-emitting element 13c and the sidewall of a corresponding second isolation opening 181a; the third sub-portion 1632 is disposed on the side of the metal structure 18 facing away from the array substrate 11. In this manner, the contact area between the third encapsulation portion 163 and the films in the display panel 10 can be enlarged, and the connection stability of the third encapsulation portion 163 can be improved.

In some embodiments, the third sub-portion 1632 is spaced from the surface of the side of the metal structure 18 facing away from the array substrate 11 because in the process of manufacturing the third light-emitting element 13c, the third light-emitting material layer and the electrode material layer 172 are formed between the third sub-portion 1632 and the metal structure 18, and in subsequent steps, the third light-emitting material layer and the electrode material layer 172 in this region are removed.

In some embodiments, in adjacent first encapsulation portion 161 and second encapsulation portion 162, the orthographic projection of the first sub-portion 1612 on the array substrate 11 overlaps the orthographic projection of the second sub-portion 1622 on the array substrate 11. In this manner, this is equivalent to that the first encapsulation portion 161 overlaps the second encapsulation portion 162 in the thickness direction of the display panel 10 so that the probability of peeling the first encapsulation portion 161 or the second encapsulation portion 162 is reduced, and the encapsulation reliability of the first encapsulation portion 161 or the second encapsulation portion 162 is improved.

In some embodiments, in the adjacent first encapsulation portion 161 and second encapsulation portion 162, part of the second sub-portion 1622 is located on one side of the first sub-portion 1612 facing away from the array substrate 11. In this manner, the second sub-portion 1622 can block the first sub-portion 1612 above the first sub-portion 1612 to prevent the first sub-portion 1612 from being lifted and undergoing peeling, thereby improving the encapsulation reliability of the first encapsulation portion 161.

In some embodiments, in adjacent second encapsulation portion 162 and third encapsulation portion 163, the orthographic projection of the second sub-portion 1622 on the array substrate 11 overlaps the orthographic projection of the third sub-portion 1632 on the array substrate 11. In this manner, this is equivalent to that the second encapsulation portion 162 overlaps the third encapsulation portion 163 in the thickness direction of the display panel 10 so that the probability of peeling the second encapsulation portion 162 or the third encapsulation portion 163 is reduced, and the encapsulation reliability of the second encapsulation portion 162 or the third encapsulation portion 163 is improved.

In some embodiments, in the adjacent second encapsulation portion 162 and third encapsulation portion 163, part of the third sub-portion 1632 is located on one side of the second sub-portion 1622 facing away from the array substrate 11. In this manner, the third sub-portion 1632 blocks the second sub-portion 1622 above the second sub-portion 1622 to prevent the second sub-portion 1622 from being lifted and undergoing peeling, thereby improving the encapsulation reliability of the second encapsulation portion 162.

Referring to FIG. 21, an example preparation method among preparation methods for a display panel 10 in the preset application specifically includes the steps below.

In S100, a substrate 111 is provided. The substrate 111 may be a rigid substrate 111 or a flexible substrate 111.

In S200, an isolation structure 12, multiple light-emitting elements 13 and a protective layer 14 are formed on one side of the substrate 111. The isolation structure 12 includes a first isolation structure 12e1 located in a first region 10a and a second isolation structure 12e2 located at a junction between the first region 10a and a second region 10b. The first isolation structure 12e1 is provided with multiple first isolation openings 12a. The multiple light-emitting elements 13 correspond to the multiple first isolation openings 12a respectively. At least part of a light-emitting element 13 of the multiple light-emitting elements 13 is disposed within a corresponding first isolation opening 12a of the multiple first isolation openings 12a. At least part of the sidewall of the second isolation structure 12e2 facing the second region 10b is covered with the protective layer 14.

In the preparation method for a display panel 10 provided in the embodiments of the present application, the protective layer 14 is disposed so that the protective layer 14 covers the at least part of the sidewall of the second isolation structure 12e2 facing the second region 10b, thereby protecting the second isolation structure 12e2. In this manner, in the process of manufacturing the display panel 10, the erosion of the sidewall of the second isolation structure 12e2 by the process solution (such as the etching solution) is weakened. For one aspect, this helps prevent the light-emitting performance of the multiple light-emitting elements 13 from being affected due to the impact on the multiple light-emitting elements 13 caused by the ion precipitation in the second isolation structure 12e2; for another aspect, this helps reduce the risk of capsulation failure caused by the erosion of the second isolation structure 12e2, thereby improving the reliability of the display panel 10.

In some embodiments, S200 in which the isolation structure 12, the multiple light-emitting elements 13 and the protective layer 14 are formed on the side of the substrate 111 specifically includes the steps below.

In S210A, the isolation structure 12 is formed on the side of the substrate 111.

In S220A, the protective layer 14 is formed on the at least part of the sidewall of the second isolation structure 12e2 facing the second region 10b.

In S230A, the multiple light-emitting elements 13 are formed on the side of the substrate 111.

In this manner, this is equivalent to that the protective layer 14 is completed before all the light-emitting elements 13 are manufactured. In this manner, the sidewall of the second isolation structure 12e2 facing the second region 10b is prevented from being eroded by the etching solution in the process of manufacturing each kind of light-emitting elements 13; and the protective performance of the protection layer 14 is improved.

In some embodiments, S200 in which the isolation structure 12, the multiple light-emitting elements 13 and the protective layer 14 are formed on the side of the substrate 111 specifically includes the steps below.

In S210B, the isolation structure 12 is formed on the side of the substrate 111.

In S220B, the protective layer 14 and the multiple light-emitting elements 13 are formed on the side of the substrate 111. In this manner, this is equivalent to that the protective layer 14 is formed synchronously in the process of manufacturing the multiple light-emitting elements 13, thereby helping reduce the manufacturing steps of the display panel 10 and the manufacturing cost.

It is to be noted that multiple first electrodes 131 spaced apart may be formed on the substrate 111 before S210B.

In some embodiments, S220B in which the protective layer 14 and the multiple light-emitting elements 13 are formed on the side of the substrate 111 specifically includes the steps below.

In S221B, multiple first light-emitting elements 13a are formed within multiple first openings 12a1 respectively. Specifically, a first light-emitting material layer 173 and an electrode material layer 172 that are stacked are formed on the side of the substrate 111 and not only cover the multiple first openings 12a1, multiple second openings 12a2 and multiple third openings 12a3 but also cover the surface of one side of the isolation structure 12 facing away from the substrate 111. The first light-emitting material layer 173 and the electrode material layer 172 within the multiple first openings 12a1 form light-emitting portions 132 of the multiple first light-emitting elements 13a and second electrodes 133 of the multiple first light-emitting elements 13a.

In S222B, multiple first encapsulation portions 161 are formed on the multiple first light-emitting elements 13a respectively, and the protective layer 14 is formed on the at least part of the sidewall of the second isolation structure 12e2 facing the second region 10b.

Specifically, S222B may include the steps below.

In S2221B, a first encapsulation material layer 175 is formed on the electrode material layer 172. The first encapsulation material layer 175 also covers the at least part of the sidewall of the second isolation structure 12e2 facing the second region 10b.

In S2222B, the first encapsulation material layer 175 is patterned to form the multiple first encapsulation portions 161 and the protective layer 14.

It is to be noted that a “triple etching process” or a “quadruple etching process” may be used in S220B in this embodiment. If the “triple etching process” is used, the first light-emitting material layer 173, the electrode material layer 172 and the first encapsulation material layer 175 within the multiple second openings 12a2 and the multiple third openings 12a3 are removed in S2222B. If the “quadruple etching process” is used, the first light-emitting material layer 173, the electrode material layer 172 and the first encapsulation material layer 175 within the multiple second openings 12a2 are only removed in S2222B, and the first light-emitting material layer 173, the electrode material layer 172 and the first encapsulation material layer 175 within the multiple third openings 12a3 are retained in S2222B. It is to be noted that the first light-emitting material layer 173, the electrode material layer 172 and the first encapsulation material layer 175 may be removed by a wet etching process.

It is to be understood that the protective layer 14 formed in this step can not only prevent the etching solution used in S222B from eroding the second isolation structure 12e2 but also prevent the etching solution used in the subsequent process of manufacturing multiple second light-emitting elements 13b and multiple third light-emitting elements 13c from eroding the second isolation structure 12e2.

After the protective layer 14 is formed, the following steps are executed.

In S223B, the multiple second light-emitting elements 13b are formed within the multiple second openings 12a2 respectively. Specifically, a second light-emitting material layer 174 and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The second light-emitting material layer 174 and the electrode material layer 172 within the multiple second openings 12a2 form light-emitting portions 132 of the multiple second light-emitting elements 13b and second electrodes 133 of the multiple second light-emitting elements 13b.

In S224B, multiple second encapsulation portions 162 are formed on the multiple second light-emitting elements 13b respectively. Specifically, S224B may include the steps below.

In S2241B, a second encapsulation material layer 176 is formed on the electrode material layer 172.

In S2242B, the second encapsulation material layer 176 is patterned to form the multiple second encapsulation portions 162.

If the “triple etching process” is used, the second light-emitting material layer 174, the electrode material layer 172 and the second encapsulation material layer 176 within the multiple first openings 12a1 and the multiple third openings 12a3 are removed in S2242B. If the “quadruple etching process” is used, referring to FIGS. 13 and 14, in S2242B, the second light-emitting material layer 174, the electrode material layer 172 and the second encapsulation material layer 176 within the multiple third openings 12a3 are first removed, and the second light-emitting material layer 174, the electrode material layer 172 and the second encapsulation material layer 176 within the multiple first openings 12a1 as well as the first light-emitting material layer 173, the electrode material layer 172 and the first encapsulation material layer 175 within the multiple third openings 12a3 are subsequently removed. It is to be noted that the second light-emitting material layer 174, the electrode material layer 172 and the second encapsulation material layer 176 may be removed by the wet etching process.

After the multiple second encapsulation portions 162 are formed, the following steps are executed.

In S225B, the multiple third light-emitting elements 13c are formed within the multiple third openings 12a3 respectively. Specifically, a third light-emitting material layer and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The third light-emitting material layer and the electrode material layer 172 within the multiple third openings 12a3 form light-emitting portions 132 of the multiple third light-emitting elements 13c and second electrodes 133 of the multiple third light-emitting elements 13c.

In S226B, multiple third encapsulation portions 163 are formed on the multiple third light-emitting elements 13c respectively. Specifically, S226B may include the steps below.

In S2261B, a third encapsulation material layer is formed on the electrode material layer 172.

In S2262B, the third light-emitting material layer, the electrode material layer 172 and the third encapsulation material layer within the multiple first openings 12a1 and the multiple second openings 12a2 are removed to form the multiple third encapsulation portions 163. It is to be noted that the third light-emitting material layer, the electrode material layer 172 and the third encapsulation material layer may be removed by the wet etching process.

In some embodiments, S220B in which the protective layer 14 and the multiple light-emitting elements 13 are formed on the side of the substrate 111 specifically includes the steps below.

In S221B, the multiple first light-emitting elements 13a are formed within the multiple first openings 12a1 respectively. Specifically, the first light-emitting material layer 173 and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The first light-emitting material layer 173 and the electrode material layer 172 within the multiple first openings 12a1 form the light-emitting portions 132 of the multiple first light-emitting elements 13a and the second electrodes 133 of the multiple first light-emitting elements 13a.

In S222B, the multiple first encapsulation portions 161 are formed on the multiple first light-emitting elements 13a respectively. Specifically, S222B may include the steps below.

In S2221B, the first encapsulation material layer 175 is formed on the electrode material layer 172.

In S2222B, the first encapsulation material layer 175 is patterned to form the multiple first encapsulation portions 161.

If the “triple etching process” is used, the first light-emitting material layer 173, the electrode material layer 172 and the first encapsulation material layer 175 within the multiple second openings 12a2 and the multiple third openings 12a3 are removed in S2222B. If the “quadruple etching process” is used, the first light-emitting material layer 173, the electrode material layer 172 and the first encapsulation material layer 175 within the multiple second openings 12a2 are only removed in S2222B, and the first light-emitting material layer 173, the electrode material layer 172 and the first encapsulation material layer 175 within the multiple third openings 12a3 are retained in S2222B. It is to be noted that the first light-emitting material layer 173, the electrode material layer 172 and the first encapsulation material layer 175 may be removed by the wet etching process.

After the multiple first encapsulation portions 161 are formed, the following steps are executed.

In S223B, the multiple second light-emitting elements 13b are formed within the multiple second openings 12a2 respectively. Specifically, the second light-emitting material layer 174 and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The second light-emitting material layer 174 and the electrode material layer 172 within the multiple second openings 12a2 form the light-emitting portions 132 of the multiple second light-emitting elements 13b and the second electrodes 133 of the multiple second light-emitting elements 13b.

In S224B, the multiple second encapsulation portions 162 are formed on the multiple second light-emitting elements 13b respectively, and the protective layer 14 is formed on the at least part of the sidewall of the second isolation structure 12e2 facing the second region 10b. Specifically, S224B may include the steps below.

In S2241B, the second encapsulation material layer 176 is formed on the electrode material layer 172. The second encapsulation material layer 176 also covers the at least part of the sidewall of the second isolation structure 12e2 facing the second region 10b.

In S2242B, the second encapsulation material layer 176 is patterned to form the multiple second encapsulation portions 162 and the protective layer 14.

If the “triple etching process” is used, the second light-emitting material layer 174, the electrode material layer 172 and the second encapsulation material layer 176 within the multiple first openings 12a1 and the multiple third openings 12a3 are removed in S2242B. If the “quadruple etching process” is used, referring to FIGS. 13 and 14, in S2242B, the second light-emitting material layer 174, the electrode material layer 172 and the second encapsulation material layer 176 within the multiple third openings 12a3 are first removed, and the second light-emitting material layer 174, the electrode material layer 172 and the second encapsulation material layer 176 within the multiple first openings 12a1 as well as the first light-emitting material layer 173, the electrode material layer 172 and the first encapsulation material layer 175 within the multiple third openings 12a3 are subsequently removed. It is to be noted that the second light-emitting material layer 174, the electrode material layer 172 and the second encapsulation material layer 176 may be removed by the wet etching process.

It is to be understood that the protective layer 14 formed in this step can not only prevent the etching solution used in S224B from eroding the second isolation structure 12e2 but also prevent the etching solution used in the subsequent process of manufacturing the multiple third light-emitting elements 13c from eroding the second isolation structure 12e2.

After the protective layer 14 is formed, the following steps are executed.

In S225B, the multiple third light-emitting elements 13c are formed within the multiple third openings 12a3 respectively. Specifically, the third light-emitting material layer and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The third light-emitting material layer and the electrode material layer 172 within the multiple third openings 12a3 form the light-emitting portions 132 of the multiple third light-emitting elements 13c and the second electrodes 133 of the multiple third light-emitting elements 13c.

In S226B, the multiple third encapsulation portions 163 are formed on the multiple third light-emitting elements 13c respectively. Specifically, S226B may include the steps below.

In S2261B, the third encapsulation material layer is formed on the electrode material layer 172.

In S2262B, the third light-emitting material layer, the electrode material layer 172 and the third encapsulation material layer within the multiple first openings 12a1 and the multiple second openings 12a2 are removed to form the multiple third encapsulation portions 163. It is to be noted that the third light-emitting material layer, the electrode material layer 172 and the third encapsulation material layer may be removed by the wet etching process.

In some embodiments, S220B in which the protective layer 14 and the multiple light-emitting elements 13 are formed on the side of the substrate 111 specifically includes the steps below.

In S221B, the multiple first light-emitting elements 13a are formed within the multiple first openings 12a1 respectively. Specifically, the first light-emitting material layer 173 and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The first light-emitting material layer 173 and the electrode material layer 172 within the multiple first openings 12a1 form the light-emitting portions 132 of the multiple first light-emitting elements 13a and the second electrodes 133 of the multiple first light-emitting elements 13a.

In S222B, the multiple first encapsulation portions 161 are formed on the multiple first light-emitting elements 13a respectively. Specifically, S222B may include the steps below.

In S2221B, the first encapsulation material layer 175 is formed on the electrode material layer 172.

In S2222B, the first encapsulation material layer 175 is patterned to form the multiple first encapsulation portions 161.

If the “triple etching process” is used, the first light-emitting material layer 173, the electrode material layer 172 and the first encapsulation material layer 175 within the multiple second openings 12a2 and the multiple third openings 12a3 are removed in S2222B. If the “quadruple etching process” is used, the first light-emitting material layer 173, the electrode material layer 172 and the first encapsulation material layer 175 within the multiple second openings 12a2 are only removed in S2222B, and the first light-emitting material layer 173, the electrode material layer 172 and the first encapsulation material layer 175 within the multiple third openings 12a3 are retained in S2222B. It is to be noted that the first light-emitting material layer 173, the electrode material layer 172 and the first encapsulation material layer 175 may be removed by the wet etching process.

After the multiple first encapsulation portions 161 are formed, the following steps are executed.

In S223B, the multiple second light-emitting elements 13b are formed within the multiple second openings 12a2 respectively. Specifically, the second light-emitting material layer 174 and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The second light-emitting material layer 174 and the electrode material layer 172 within the multiple second openings 12a2 form the light-emitting portions 132 of the multiple second light-emitting elements 13b and the second electrodes 133 of the multiple second light-emitting elements 13b.

In S224B, the multiple second encapsulation portions 162 are formed on the multiple second light-emitting elements 13b respectively. Specifically, S224B may include the steps below.

In S2241B, the second encapsulation material layer 176 is formed on the electrode material layer 172.

In S2242B, the second encapsulation material layer 176 is patterned to form the multiple second encapsulation portions 162 and the protective layer 14.

If the “triple etching process” is used, the second light-emitting material layer 174, the electrode material layer 172 and the second encapsulation material layer 176 within the multiple first openings 12a1 and the multiple third openings 12a3 are removed in S2242B. If the “quadruple etching process” is used, referring to FIGS. 13 and 14, in S2242B, the second light-emitting material layer 174, the electrode material layer 172 and the second encapsulation material layer 176 within the multiple third openings 12a3 are first removed, and the second light-emitting material layer 174, the electrode material layer 172 and the second encapsulation material layer 176 within the multiple first openings 12a1 as well as the first light-emitting material layer 173, the electrode material layer 172 and the first encapsulation material layer 175 within the multiple third openings 12a3 are subsequently removed. It is to be noted that the second light-emitting material layer 174, the electrode material layer 172 and the second encapsulation material layer 176 may be removed by the wet etching process.

After the multiple second encapsulation portions 162 are formed, the following steps are executed.

In S225B, the multiple third light-emitting elements 13c are formed within the multiple third openings 12a3 respectively. Specifically, the third light-emitting material layer and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The third light-emitting material layer and the electrode material layer 172 within the multiple third openings 12a3 form the light-emitting portions 132 of the multiple third light-emitting elements 13c and the second electrodes 133 of the multiple third light-emitting elements 13c.

In S226B, the multiple third encapsulation portions 163 are formed on the multiple third light-emitting elements 13c respectively, and the protective layer 14 is formed on the at least part of the sidewall of the second isolation structure 12e2 facing the second region 10b. Specifically, S226B may include the steps below.

In S2261B, the third encapsulation material layer is formed on the electrode material layer 172. The third encapsulation material layer also covers the at least part of the sidewall of the second isolation structure 12e2 facing the second region 10b.

In S2262B, the third light-emitting material layer, the electrode material layer 172 and the third encapsulation material layer within the multiple first openings 12a1 and the multiple second openings 12a2 are removed to form the multiple third encapsulation portions 163. It is to be noted that the third light-emitting material layer, the electrode material layer 172 and the third encapsulation material layer may be removed by the wet etching process. It is to be understood that the protective layer 14 formed in this step can prevent the etching solution used in S226B from eroding the second isolation structure 12e2.

In some embodiments, S200 in which the isolation structure 12, the multiple light-emitting elements 13 and the protective layer 14 are formed on the side of the substrate 111 specifically includes the steps below.

In S210C, an isolation structure material layer is formed on the side of the substrate 111. The isolation structure material layer may include multiple metal layers.

In S220C, first etching is performed on the isolation structure material layer to form the multiple first openings 12a1 and the sidewall of the second isolation structure 12e2 facing the second region 10b. Specifically, this is equivalent to that the isolation structure material layer is side-etched for the first time to form the multiple first openings 12a1 and the initial morphology of the second isolation structure 12e2 facing the second region 10b. It is to be noted that an etching blocking layer may be used for protecting regions that do not require etching.

In S230C, the multiple first light-emitting elements 13a are formed within the multiple first openings 12a1 respectively. Specifically, the first light-emitting material layer 173 and the electrode material layer 172 that are stacked are formed on the side of the substrate 111 and not only cover the multiple first openings 12a1 but also cover the surface of one side of the isolation structure material layer facing away from the substrate 111. The first light-emitting material layer 173 and the electrode material layer 172 within the multiple first openings 12a1 form the light-emitting portions 132 of the multiple first light-emitting elements 13a and the second electrodes 133 of the multiple first light-emitting elements 13a.

In S240C, the multiple first encapsulation portions 161 are formed on the multiple first light-emitting elements 13a respectively. Specifically, S240C may include the steps below.

In S241C, the first encapsulation material layer 175 is formed on the electrode material layer 172.

In S242C, the first encapsulation material layer 175 is patterned to form the multiple first encapsulation portions 161.

In S250C, the sidewall of the second isolation structure 12e2 facing the second region 10b is side-etched. In this manner, this is equivalent to that the second isolation structure 12e2 is side-etched for the second time to form the final morphology of the second isolation structure 12e2 facing the second region 10b. In this manner, a bottom cut on one side of the second isolation structure 12e2 facing the second region 10b can be larger. It is to be noted that the etching blocking layer may be used for protecting the regions that do not require etching.

In S260C, second etching is performed on the isolation structure material layer to form the multiple second openings 12a2. Specifically, this is equivalent to that the isolation structure material layer is side-etched for the third time to form the multiple second openings 12a2. It is to be noted that the etching blocking layer may be used for protecting the regions that do not require etching.

In S270C, the multiple second light-emitting elements 13b are formed within the multiple second openings 12a2 respectively. Specifically, the second light-emitting material layer 174 and the electrode material layer 172 that are stacked are formed on the side of the substrate 111 and not only cover the multiple first openings 12a1 and the multiple second openings 12a2 but also cover the surface of the side of the isolation structure material layer facing away from the substrate 111. The second light-emitting material layer 174 and the electrode material layer 172 within the multiple second openings 12a2 form the light-emitting portions 132 of the multiple second light-emitting elements 13b and the second electrodes 133 of the multiple second light-emitting elements 13b.

In S280C, the multiple second encapsulation portions 162 are formed on the multiple second light-emitting elements 13b respectively, and the protective layer 14 is formed on the at least part of the sidewall of the second isolation structure 12e2 facing the second region 10b. Specifically, S280C may include the steps below.

In S281C, the second encapsulation material layer 176 is formed on the electrode material layer 172. The second encapsulation material layer 176 also covers the at least part of the sidewall of the second isolation structure 12e2 facing the second region 10b.

In S282C, the second encapsulation material layer 176 is patterned to form the multiple second encapsulation portions 162 and the protective layer 14.

Specifically, the second light-emitting material layer 174, the electrode material layer 172 and the second encapsulation material layer 176 within the multiple first openings 12a1 are removed. The second light-emitting material layer 174, the electrode material layer 172 and the second encapsulation material layer 176 on the surface of the side of the isolation structure material layer facing away from the substrate 11 are also removed. It is to be noted that the second light-emitting material layer 174, the electrode material layer 172 and the second encapsulation material layer 176 may be removed by the wet etching process.

It is to be understood that the protective layer 14 formed in this step can not only prevent the etching solution used in S282C from eroding the second isolation structure 12e2 but also prevent the etching solution used in the subsequent process of manufacturing the multiple third light-emitting elements 13c from eroding the second isolation structure 12e2.

In S290C, third etching is performed on the isolation structure material layer to form the multiple third openings 12a3. Specifically, this is equivalent to that the isolation structure material layer is side-etched for the fourth time to form the multiple third openings 12a3. It is to be noted that the etching blocking layer may be used for protecting the regions that do not require etching.

In S2100C, the multiple third light-emitting elements 13c are formed within the multiple third openings 12a3 respectively. Specifically, the third light-emitting material layer and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The third light-emitting material layer and the electrode material layer 172 within the multiple third openings 12a3 form the light-emitting portions 132 of the multiple third light-emitting elements 13c and the second electrodes 133 of the multiple third light-emitting elements 13c.

In S2110C, the multiple third encapsulation portions 163 are formed on the multiple third light-emitting elements 13c respectively. Specifically, S2110C may include the steps below.

In S2111C, the third encapsulation material layer is formed on the electrode material layer 172.

In S2112C, the third light-emitting material layer, the electrode material layer 172 and the third encapsulation material layer within the multiple first openings 12a1 and the multiple second openings 12a2 are removed to form the multiple third encapsulation portions 163. It is to be noted that the third light-emitting material layer, the electrode material layer 172 and the third encapsulation material layer may be removed by the wet etching process.

In some embodiments, S200 in which the isolation structure 12, the multiple light-emitting elements 13 and the protective layer 14 are formed on the side of the substrate 111 specifically includes the steps below.

In S210C, the isolation structure material layer is formed on the side of the substrate 111. The isolation structure material layer may include the multiple metal layers.

In S220C, the first etching is performed on the isolation structure material layer to form the multiple first openings 12a1 and the sidewall of the second isolation structure 12e2 facing the second region 10b. Specifically, this is equivalent to that the isolation structure material layer is side-etched for the first time to form the multiple first openings 12a1 and the initial morphology of the second isolation structure 12e2 facing the second region 10b. It is to be noted that the etching blocking layer may be used for protecting the regions that do not require etching.

In S230C, the multiple first light-emitting elements 13a are formed within the multiple first openings 12a1 respectively. Specifically, the first light-emitting material layer 173 and the electrode material layer 172 that are stacked are formed on the side of the substrate 111 and not only cover the multiple first openings 12a1 but also cover the surface of the side of the isolation structure material layer facing away from the substrate 111. The first light-emitting material layer 173 and the electrode material layer 172 within the multiple first openings 12a1 form the light-emitting portions 132 of the multiple first light-emitting elements 13a and the second electrodes 133 of the multiple first light-emitting elements 13a.

In S240C, the multiple first encapsulation portions 161 are formed on the multiple first light-emitting elements 13a respectively. Specifically, S240C may include the steps below.

In S241C, the first encapsulation material layer 175 is formed on the electrode material layer 172.

In S242C, the first encapsulation material layer 175 is patterned to form the multiple first encapsulation portions 161.

In S250C, the second etching is performed on the isolation structure material layer to form the multiple second openings 12a2. Specifically, this is equivalent to that the isolation structure material layer is side-etched for the second time to form the multiple second openings 12a2. It is to be noted that the etching blocking layer may be used for protecting the regions that do not require etching.

In S260C, the multiple second light-emitting elements 13b are formed within the multiple second openings 12a2 respectively. Specifically, the second light-emitting material layer 174 and the electrode material layer 172 that are stacked are formed on the side of the substrate 111 and not only cover the multiple first openings 12a1 and the multiple second openings 12a2 but also cover the surface of the side of the isolation structure material layer facing away from the substrate 111. The second light-emitting material layer 174 and the electrode material layer 172 within the multiple second openings 12a2 form the light-emitting portions 132 of the multiple second light-emitting elements 13b and the second electrodes 133 of the multiple second light-emitting elements 13b.

In S270C, the multiple second encapsulation portions 162 are formed on the multiple second light-emitting elements 13b respectively.

Specifically, S270C may include the steps below.

In S271C, the second encapsulation material layer 176 is formed on the electrode material layer 172.

In S272C, the second encapsulation material layer 176 is patterned to form the multiple second encapsulation portions 162.

Specifically, the second light-emitting material layer 174, the electrode material layer 172 and the second encapsulation material layer 176 within the multiple first openings 12a1 are removed. The second light-emitting material layer 174, the electrode material layer 172 and the second encapsulation material layer 176 on the surface of the side of the isolation structure material layer facing away from the substrate 11 are also removed. It is to be noted that the second light-emitting material layer 174, the electrode material layer 172 and the second encapsulation material layer 176 may be removed by the wet etching process.

In S280C, the sidewall of the second isolation structure 12e2 facing the second region 10b is side-etched. In this manner, this is equivalent to that the second isolation structure 12e2 is side-etched for the second time to form the final morphology of the second isolation structure 12e2 facing the second region 10b. In this manner, the bottom cut on the side of the second isolation structure 12e2 facing the second region 10b can be larger. It is to be noted that the etching blocking layer may be used for protecting the regions that do not require etching.

In S290C, the third etching is performed on the isolation structure material layer to form the multiple third openings 12a3. It is to be noted that the etching blocking layer may be used for protecting the regions that do not require etching.

In S2100C, the multiple third light-emitting elements 13c are formed within the multiple third openings 12a3 respectively. Specifically, the third light-emitting material layer and the electrode material layer 172 that are stacked are formed on the side of the substrate 111 and not only cover the multiple first openings 12a1, the multiple second openings 12a2 and the multiple third openings 12a3 but also cover the surface of the side of the isolation structure 12 facing away from the substrate 111. The third light-emitting material layer and the electrode material layer 172 within the multiple third openings 12a3 form the light-emitting portions 132 of the multiple third light-emitting elements 13c and the second electrodes 133 of the multiple third light-emitting elements 13c.

In S2110C, the multiple third encapsulation portions 163 are formed on the multiple third light-emitting elements 13c respectively, and the protective layer 14 is formed on the at least part of the sidewall of the second isolation structure 12e2 facing the second region 10b. Specifically, S2110C may include the steps below.

In S2111C, the third encapsulation material layer is formed on the electrode material layer 172. The third encapsulation material layer also covers the at least part of the sidewall of the second isolation structure 12e2 facing the second region 10b.

In S2112C, the third light-emitting material layer, the electrode material layer 172 and the third encapsulation material layer within the multiple first openings 12a1 and the multiple second openings 12a2 are removed to form the multiple third encapsulation portions 163 and the protective layer 14. It is to be noted that the third light-emitting material layer, the electrode material layer 172 and the third encapsulation material layer may be removed by the wet etching process. It is to be understood that the protective layer 14 formed in this step can prevent the etching solution used in S2112C from eroding the second isolation structure 12e2.

A display device provided in the present application includes the display panel of any one of the preceding embodiments.

The display device may be a laptop computer, a mobile phone, a wireless device, a personal digital assistant (PDA), a handheld or portable computer, a GPS (Global Positioning System) receiver/navigator, a camera, an MP4 video player, a camcorder, a game console, a watch, a clock, a calculator, a television monitor, a flat-panel display, a computer monitor, a car display (such as an odometer display), a navigator, a cockpit controller and/or display, a display of a camera view (such as a display of a rearview camera in a vehicle), an electronic photo, an electronic billboard or sign, or a projector.

The preceding embodiments are several embodiments of the present application. These embodiments are described in a specific and detailed manner but cannot be understood as a limit to the scope of the present application. It is to be noted that for those of ordinary skill in the art, several modifications and improvements can be made without departing from the concept of the present application, and these modifications and improvements are within the scope of the present application. Therefore, the scope of the present application is defined by the appended claims.

What is claimed is:

1. A display panel, comprising a first region and a second region adjacent to the first region and comprising:
a substrate;
an isolation structure disposed on one side of the substrate and comprising a first isolation structure located in the first region and a second isolation structure located at a junction between the first region and the second region, wherein the first isolation structure is provided with a plurality of first isolation openings;
a plurality of light-emitting elements disposed on the side of the substrate and corresponding to the plurality of first isolation openings, wherein at least part of a light-emitting element of the plurality of light-emitting elements is disposed within a corresponding first isolation opening of the plurality of first isolation openings; and
a protective layer covering at least part of a sidewall of the second isolation structure facing the second region.

2. The display panel of claim 1, wherein the first region is a display region, and the second region is a bezel region;
the bezel region is around a periphery of the display region;
the isolation structure further comprises a third isolation structure located in the bezel region and electrically connected to the first isolation structure;
the display panel further comprises an array film disposed between the substrate and the isolation structure, and the third isolation structure is electrically connected to wires in the array film;
the protective layer further covers at least part of a sidewall of the third isolation structure;
the display panel further comprises dams disposed in the bezel region and around a periphery of the isolation structure;
the display panel further comprises an organic encapsulation layer disposed on sides of the plurality of light-emitting elements facing away from the substrate and one side of the isolation structure facing away from the substrate;
the organic encapsulation layer covers at least a part of dames among the dams; and
the display panel further comprises an inorganic encapsulation layer at least covering one side of the organic encapsulation layer facing away from the substrate.

3. The display panel of claim 1, wherein the first region is a display region, and the second region is a hole-punch region, wherein a transmittance of the hole-punch region is greater than a transmittance of the display region;
the isolation structure is provided with a first light-transmissive hole located in the hole-punch region;
the display region is around a periphery of the hole-punch region; or
the display panel comprises a first display sub-region and a second display sub-region that are adjacent to each other, wherein a transmittance of the first display sub-region is less than a transmittance of the second display sub-region; the second display sub-region is provided with a plurality of second regions spaced apart, and remaining regions of the second display sub-region and all regions of the first display sub-region form the first region;
the isolation structure comprises a plurality of second light-transmissive holes disposed in one-to-one correspondence in the plurality of second regions, and the protective layer comprises a plurality of protective sub-layers in one-to-one correspondence with the plurality of second light-transmissive holes, wherein each of the plurality of protective sub-layers covers a sidewall of a respective one of the plurality of second light-transmissive holes; and
the first display sub-region is around a periphery of the second display sub-region.

4. The display panel of claim 1, wherein the isolation structure comprises a conductive portion and a blocking portion that are stacked in a direction facing away from the substrate; an outer contour of an orthographic projection of the blocking portion on the substrate is located at a periphery of an outer contour of an orthographic projection of the conductive portion on the substrate;
a light-emitting element of the plurality of light-emitting elements comprises a first electrode, a light-emitting portion and a second electrode that are stacked in the direction facing away from the substrate, wherein the second electrode is electrically connected to the conductive portion;
the protective layer at least covers at least part of a wall surface of the conductive portion of the second isolation structure facing the second region;
the protective layer further covers a wall surface of the blocking portion of the second isolation structure facing the second region;
the protective layer comprises a main body covering the at least part of the sidewall of the second isolation structure facing the second region; and
a material of the protective layer is an organic material or an inorganic material.

5. The display panel of claim 4, wherein the protective layer further comprises a first extension portion connected to the main body and disposed on one side of the blocking portion facing away from the substrate, wherein a surface of one side of the first extension portion facing the substrate is spaced from a surface of the side of the blocking portion facing away from the substrate;
the second isolation structure is provided with a first trench disposed on one side of the isolation structure facing away from the substrate; the protective layer further comprises a second extension portion connected to one end of the first extension portion facing away from the main body and covering at least part of a trench wall of the first trench;
the first trench comprises a first sub-trench and a first opening portion, wherein the first opening portion is located on one side of the first sub-trench facing away from the substrate, and an orthographic projection of the first opening portion on the substrate falls within an orthographic projection of the first sub-trench on the substrate;
the first opening portion passes through the blocking portion in a thickness direction of the substrate, and the first sub-trench is disposed on a surface of one side of the conductive portion facing away from the substrate;
a size of the first opening portion in a first direction is less than a size of the first sub-trench in the first direction, wherein the first direction is perpendicular to the thickness direction of the substrate and an extension direction of the first trench; and
a light-emitting material film and an electrode material layer are stacked between the first extension portion and the blocking portion, and the light-emitting material film is located between the blocking portion and the electrode material layer.

6. The display panel of claim 5, wherein the protective layer further comprises a coverage portion connected to the main body, wherein one end of the coverage portion is connected to one end of the main body facing away from the blocking portion, and another end of the coverage portion extends in a direction facing away from the second isolation structure; and
the display panel further comprises an insulating structure disposed between the insolation structure and the substrate.

7. The display panel of claim 6, wherein at least part of a surface of one side of the coverage portion facing the substrate is spaced from a surface of one side of the insulating structure facing away from the substrate;
a first gap is present between the end of the main body facing away from the blocking portion and a sidewall of one side of the second isolation structure facing the second region, and an entire surface of the side of the coverage portion facing the substrate is spaced from the surface of the side of the insulating structure facing away from the substrate;
the display panel further comprises a filing layer, wherein at least part of the filling layer is filled in the first gap and filled between the coverage portion and the insulating structure;
the filling layer comprises an organic material; and
the display panel further comprises an organic encapsulation layer disposed on sides of the plurality of light-emitting elements facing away from the substrate and one side of the isolation structure facing away from the substrate; the filling layer is disposed in a same layer and made of a same material as the organic encapsulation layer.

8. The display panel of claim 6, wherein one end of the coverage portion facing the main body contacts a surface of one side of the insulating structure facing away from the substrate, and one end of the coverage portion facing away from the main body is spaced from the insulating structure;
the main body covers an entire sidewall of the second isolation structure facing the second region;
one end of the blocking portion facing a corresponding first isolation opening of the plurality of first isolation openings extends towards a center of the corresponding first isolation opening and protrudes from a wall surface of one side of the conductive portion facing the corresponding first isolation opening, and one end of the blocking portion facing the second region extends towards the second region and protrudes from a wall surface of one side of the conductive portion facing the second region,
a portion of the blocking portion protruding from the wall surface of the side of the conductive portion facing the corresponding first isolation opening is a first blocking sub-portion, wherein the first blocking sub-portion protrudes from a wall surface of the conductive portion by a first length; a portion of the blocking portion protruding from the wall surface of the side of the conductive portion facing the second region is a second blocking sub-portion, wherein the second blocking sub-portion protrudes from the wall surface of the conductive portion by a second length;
the second length is greater than the first length;
a ratio of the second length to the first direction ranges from 1 to 3; and
the isolation structure is a metal structure, and a density of a metal structure of the first region is greater than a density of a metal structure of the second region.

9. The display panel of claim 6, wherein the insulating structure located in the second region is provided with a second trench, and the protective layer further comprises a third extension portion connected to one end of the coverage portion facing away from the main body and covering at least part of a trench wall of the second trench;
the second trench comprises a second sub-trench and a second opening portion, wherein the second opening portion is located on one side of the second sub-trench facing away from the substrate, and an orthographic projection of the second opening portion on the substrate falls within an orthographic projection of the second sub-trench on the substrate;
the insulating structure comprises a planarization layer and a pixel defining layer that are stacked, wherein the planarization layer is disposed between the substrate and the pixel defining layer; the second opening portion passes through the pixel defining layer in the thickness direction of the substrate, and the second sub-trench is disposed on a surface of one side of the planarization layer facing away from the substrate;
a size of the second opening portion in a second direction is less than a size of the second sub-trench in the second direction, wherein the second direction is perpendicular to the thickness direction of the substrate and an extension direction of the second trench;
a light-emitting material film and an electrode material layer are stacked between the coverage portion and the insulating structure, and the light-emitting material film is located between the insulating structure and the electrode material layer; and
the pixel defining layer is provided with a plurality of pixel openings, wherein the plurality of first isolation openings pass through the plurality of pixel openings respectively, and the plurality of light-emitting elements correspond to the plurality of pixel openings respectively.

10. The display panel of claim 1, wherein the plurality of light-emitting elements comprise a plurality of first light-emitting elements, a plurality of second light-emitting elements and a plurality of third light-emitting elements, wherein the plurality of first light-emitting elements, the plurality of second light-emitting elements and the plurality of third light-emitting elements are configured to emit light of different colors respectively;
the display panel further comprises a plurality of first encapsulation portions, a plurality of second encapsulation portions and a plurality of third encapsulation portions, wherein the plurality of first encapsulation portions are in one-to-one correspondence with the plurality of first light-emitting elements, and a first encapsulation portion of the plurality of first encapsulation portions is disposed on one side of a corresponding first light-emitting element of the plurality of first light-emitting elements facing away from the substrate; the plurality of second encapsulation portions are in one-to-one correspondence with the plurality of second light-emitting elements, and a second encapsulation portion of the plurality of second encapsulation portions is disposed on one side of a corresponding second light-emitting element of the plurality of second light-emitting elements facing away from the substrate; the plurality of third encapsulation portions are in one-to-one correspondence with the plurality of third light-emitting elements, and a third encapsulation portion of the plurality of third encapsulation portions is disposed on one side of a corresponding third light-emitting element of the plurality of third light-emitting elements facing away from the substrate;
any one of the first encapsulation portion, the second encapsulation portion, or the third encapsulation portion is disposed in a same layer and made of a same material as the protective layer;
the first encapsulation portion, the second encapsulation portion and the third encapsulation portion are all inorganic films.

11. The display panel of claim 10, wherein the first encapsulation portion comprises a first main portion and a first sub-portion connected to the first main portion, wherein the first main portion covers the first light-emitting element and a sidewall of a corresponding first isolation opening of the plurality of first isolation openings, and the first sub-portion is disposed on one side of the isolation structure facing away from the substrate;
the first sub-portion is spaced from a surface of the side of the isolation structure facing away from the substrate;
the second encapsulation portion comprises a second main portion and a second sub-portion connected to the second main portion, wherein the second main portion covers the second light-emitting element and a sidewall of a corresponding first isolation opening of the plurality of first isolation openings, and the second sub-portion is disposed on the side of the isolation structure facing away from the substrate;
the second sub-portion is spaced from the surface of the side of the isolation structure facing away from the substrate;
the third encapsulation portion comprises a third main portion and a third sub-portion connected to the third main portion, wherein the third main portion covers the third light-emitting element and a sidewall of a corresponding first isolation opening of the plurality of first isolation openings, and the third sub-portion is disposed on the side of the isolation structure facing away from the substrate;
the third sub-portion is spaced from the surface of the side of the isolation structure facing away from the substrate.

12. The display panel of claim 11, wherein in adjacent first encapsulation portion and second encapsulation portion, an orthographic projection of the first sub-portion on the substrate overlaps an orthographic projection of the second sub-portion on the substrate;
in the adjacent first encapsulation portion and second encapsulation portion, the first sub-portion and the second sub-portion are spaced apart;
in the adjacent first encapsulation portion and second encapsulation portion, part of the second sub-portion is located on one side of the first sub-portion facing away from the substrate;
in adjacent second encapsulation portion and third encapsulation portion, an orthographic projection of the second sub-portion on the substrate overlaps an orthographic projection of the third sub-portion on the substrate;
in the adjacent second encapsulation portion and third encapsulation portion, the second sub-portion and the third sub-portion are spaced apart; and
in the adjacent second encapsulation portion and third encapsulation portion, part of the third sub-portion is located on one side of the second sub-portion facing away from the substrate.

13. A preparation method for a display panel, wherein the display panel comprises a first region and a second region adjacent to the first region; and
the preparation method comprises:
providing a substrate; and
forming an isolation structure, a plurality of light-emitting elements and a protective layer on one side of the substrate;
wherein the isolation structure comprises a first isolation structure located in the first region and a second isolation structure located at a junction between the first region and the second region, wherein the first isolation structure is provided with a plurality of first isolation openings; the plurality of light-emitting elements correspond to the plurality of first isolation openings respectively, and at least part of a light-emitting element of the plurality of light-emitting elements is disposed within a corresponding first isolation opening of the plurality of first isolation openings; at least part of a sidewall of the second isolation structure facing the second region is covered with the protective layer.

14. The preparation method for a display panel of claim 13, wherein forming the isolation structure, the plurality of light-emitting elements and the protective layer on the side of the substrate comprises:
forming the isolation structure on the side of the substrate;
forming the protective layer on the at least part of the sidewall of the second isolation structure facing the second region; and
forming the plurality of light-emitting elements on the side of the substrate.

15. The preparation method for a display panel of claim 13, wherein forming the isolation structure, the plurality of light-emitting elements and the protective layer on the side of the substrate comprises:
forming the isolation structure on the side of the substrate; and
forming the protective layer and the plurality of light-emitting elements on the side of the substrate.

16. The preparation method for a display panel of claim 15, wherein the plurality of light-emitting elements comprise a plurality of first light-emitting elements, a plurality of second light-emitting elements and a plurality of third light-emitting elements, wherein the plurality of first light-emitting elements, the plurality of second light-emitting elements and the plurality of third light-emitting elements are configured to emit light of different colors respectively; the plurality of first isolation openings comprise a plurality of first openings, a plurality of second openings and a plurality of third openings; and
wherein forming the protective layer and the plurality of light-emitting elements on the side of the substrate comprises:
forming the plurality of first light-emitting elements within the plurality of first openings respectively;
forming a plurality of first encapsulation portions on the plurality of first light-emitting elements respectively and forming the protective layer on the at least part of the sidewall of the second isolation structure facing the second region;
forming the plurality of second light-emitting elements within the plurality of second openings respectively;
forming a plurality of second encapsulation portions on the plurality of second light-emitting elements respectively;
forming the plurality of third light-emitting elements within the plurality of third openings respectively; and
forming a plurality of third encapsulation portions on the plurality of third light-emitting elements respectively.

17. The preparation method for a display panel of claim 15, wherein the plurality of light-emitting elements comprise a plurality of first light-emitting elements, a plurality of second light-emitting elements and a plurality of third light-emitting elements, wherein the plurality of first light-emitting elements, the plurality of second light-emitting elements and the plurality of third light-emitting elements are configured to emit light of different colors respectively; the plurality of first isolation openings comprise a plurality of first openings, a plurality of second openings and a plurality of third openings; and
wherein forming the protective layer and the plurality of light-emitting elements on the side of the substrate comprises:
forming the plurality of first light-emitting elements within the plurality of first openings respectively;
forming a plurality of first encapsulation portions on the plurality of first light-emitting elements respectively;
forming the plurality of second light-emitting elements within the plurality of second openings respectively;
forming a plurality of second encapsulation portions on the plurality of second light-emitting elements respectively and forming the protective layer on the at least part of the sidewall of the second isolation structure facing the second region;
forming the plurality of third light-emitting elements within the plurality of third openings respectively; and
forming a plurality of third encapsulation portions on the plurality of third light-emitting elements respectively.

18. The preparation method for a display panel of claim 15, wherein the plurality of light-emitting elements comprise a plurality of first light-emitting elements, a plurality of second light-emitting elements and a plurality of third light-emitting elements, wherein the plurality of first light-emitting elements, the plurality of second light-emitting elements and the plurality of third light-emitting elements are configured to emit light of different colors respectively; the plurality of first isolation openings comprise a plurality of first openings, a plurality of second openings and a plurality of third openings; and
wherein forming the protective layer and the plurality of light-emitting elements on the side of the substrate comprises:
forming the plurality of first light-emitting elements within the plurality of first openings respectively;
forming a plurality of first encapsulation portions on the plurality of first light-emitting elements respectively;
forming the plurality of second light-emitting elements within the plurality of second openings respectively;
forming a plurality of second encapsulation portions on the plurality of second light-emitting elements respectively;
forming the plurality of third light-emitting elements within the plurality of third openings respectively; and
forming a plurality of third encapsulation portions on the plurality of third light-emitting elements respectively and forming the protective layer on the at least part of the sidewall of the second isolation structure facing the second region.

19. The preparation method for a display panel of claim 13, wherein the plurality of light-emitting elements comprise a plurality of first light-emitting elements, a plurality of second light-emitting elements and a plurality of third light-emitting elements, wherein the plurality of first light-emitting elements, the plurality of second light-emitting elements and the plurality of third light-emitting elements are configured to emit light of different colors respectively; the plurality of first isolation openings comprise a plurality of first openings, a plurality of second openings and a plurality of third openings; and
wherein forming the isolation structure, the plurality of light-emitting elements and the protective layer on the side of the substrate comprises:
forming an isolation structure material layer on the side of the substrate;
performing first etching on the isolation structure material layer to form the plurality of first openings and the sidewall of the second isolation structure facing the second region;
forming the plurality of first light-emitting elements within the plurality of first openings respectively;
forming a plurality of first encapsulation portions on the plurality of first light-emitting elements respectively;
performing side-etching on the sidewall of the second isolation structure facing the second region;
performing second etching on the isolation structure material layer to form the plurality of second openings;
forming the plurality of second light-emitting elements within the plurality of second openings respectively;
forming a plurality of second encapsulation portions on the plurality of second light-emitting elements respectively and forming the protective layer on the at least part of the sidewall of the second isolation structure facing the second region;
performing third etching on the isolation structure material layer to form the plurality of third openings;
forming the plurality of third light-emitting elements within the plurality of third openings respectively; and
forming a plurality of third encapsulation portions on the plurality of third light-emitting elements respectively.

20. The preparation method for a display panel of claim 13, wherein the plurality of light-emitting elements comprise a plurality of first light-emitting elements, a plurality of second light-emitting elements and a plurality of third light-emitting elements, wherein the plurality of first light-emitting elements, the plurality of second light-emitting elements and the plurality of third light-emitting elements are configured to emit light of different colors respectively; the plurality of first isolation openings comprise a plurality of first openings, a plurality of second openings and a plurality of third openings; and
wherein forming the isolation structure, the plurality of light-emitting elements and the protective layer on the side of the substrate comprises:
forming an isolation structure material layer on the side of the substrate;
performing first etching on the isolation structure material layer to form the plurality of first openings and the sidewall of the second isolation structure facing the second region;
forming the plurality of first light-emitting elements within the plurality of first openings respectively;
forming a plurality of first encapsulation portions on the plurality of first light-emitting elements respectively;
performing second etching on the isolation structure material layer to form the plurality of second openings;
forming the plurality of second light-emitting elements within the plurality of second openings respectively;
forming a plurality of second encapsulation portions on the plurality of second light-emitting elements respectively;
performing side-etching on the sidewall of the second isolation structure facing the second region;
performing third etching on the isolation structure material layer to form the plurality of third openings;
forming the plurality of third light-emitting elements within the plurality of third openings respectively; and
forming a plurality of third encapsulation portions on the plurality of third light-emitting elements respectively and forming the protective layer on the at least part of the sidewall of the second isolation structure facing the second region.
